(19) United States
(12) Patent Application Publication
(10) Pub. No.: US 2019/0011283 A1
(43) Pub. Date: Jan. 10, 2019

(54) PROCESSING OF RESOURCE CONSUMPTION DATA VIA MONITORING PHYSICALLY OBSERVABLE BEHAVIORS OF AN EXISTING RESOURCE METER AND PROVISION OF FUNCTIONALITIES BASED ON PROCESSING OF RESOURCE CONSUMPTION DATA

(71) Applicant: Wattcost Pty Ltd, Ultimo (AU)

(72) Inventors: David Soutar, Ultimo (AU); Demetrious Harrington, Ultimo (AU); Christopher Alfred, Ultimo (AU)

(21) Appl. No.: 15/753,946

(22) PCT Filed: Aug. 21, 2015
(86) PCT No.: PCT/AU2015/000502

§ 371 Date: Feb. 20, 2018

(51) Int. Cl. G01D 4/00; G01R 22/06; H04L 29/08

(52) U.S. Cl. CPC G01D 4/008; G01R 22/063; H04L 67/306; H04L 67/12; G01D 4/004

(57) ABSTRACT

The present invention relates to devices, frameworks and methodologies configured to enable processing of resource consumption data via monitoring physically observable behaviors of an existing resource meter, and devices, frameworks and methodologies configured to enable provision of functionalities based on processing of resource consumption data. Some embodiments of the invention have been particularly developed for application in the context of enabling real-time monitoring of meter data, for example electrical meters, and the provision of functionality of users based on processing of monitored data. While some embodiments will be described herein with particular reference to that application, it will be appreciated that the invention is not limited to such a field of use, and is applicable in broader contexts.

### FIELD OF THE INVENTION

The present invention relates to devices, frameworks and methodologies configured to enable processing of resource consumption data via monitoring physically observable behaviors of an existing resource meter, and devices, frameworks and methodologies configured to enable provision of functionalities based on processing of resource consumption data. Some embodiments of the invention have been particularly developed for application in the context of enabling real-time monitoring of meter data, for example electrical meters, and the provision of functionality of users based on processing of monitored data. While some embodiments will be described herein with particular reference to that application, it will be appreciated that the invention is not limited to such a field of use, and is applicable in broader contexts.

### BACKGROUND

Any discussion of the background art throughout the specification should in no way be considered as an admission that such art is widely known or forms part of common general knowledge in the field.

Meters configured to monitor resource consumption have been widely used for many years. Common examples include electrical meters, gas meters, and other meters used by utility companies to track consumption at user sites. Traditionally, meters have been read manually, a process that requires human access to a site, and is often plagued by errors. More recently, various forms of “smart meter” have been developed, which are able to autonomously communicate meter data to a central hub. However, the rollout of such meters to all sites is an inherently a slow process, and existing smart meter technology only allows for limited forms of processing (for example due to low resolution monitoring).

### SUMMARY OF THE INVENTION

It is an object of the present invention to overcome or ameliorate at least one of the disadvantages of the prior art, or to provide a useful alternative.

One embodiment provides a device that is configured to monitor a physical resource consumption meter, the device including:

an input, wherein the input is configured to receive data from a sensor device, wherein the sensor device is configured to monitor physical behaviour of a meter component of the physical resource consumption meter, wherein the meter component includes at least one of the following:

a meter component that varies velocity proportionally to resource consumption;

a meter component that varies display of visible light proportionally to resource consumption; and

a meter component that varies current proportionally to resource consumption;

a communications module configured to enable communications with a remote server device; and

a microprocessor that is coupled to the input and the communications module, wherein the microprocessor is configured to execute software instructions, wherein the software instructions configure:

operation of the sensor device;

processing of data received from the sensor device thereby to define data for transmission to the remote server device; and

operation of the communications module; and

a battery power supply, which is configured to power at least the sensor; the communications module; and the microprocessor.

One embodiment provides a device wherein configuring operation of the sensor device includes:

cyclically transitioning the sensor between an active state and an inactive state based on an activation cycle, wherein the activation cycle defines:

(i) a time period for which the sensor is in an active state; and

(ii) a time period for which the sensor is in an inactive state;

selectively modifying the activation cycle based on a power management protocol.

One embodiment provides a device wherein: in the inactive state the sensor monitors meter component activity an provides an interrupt signal upon identification of a threshold condition; and in the active state the sensor communicates one or more values read from the monitoring of the meter component.

One embodiment provides a device wherein configuring operation of the communications module includes:

configuring the device to enter an active communications state based on a set of transmission rules, wherein the device is configured to transmit data to the remote server when in the active communications state; and

maintaining the communications module in an inactive or low-power state when not in the active communications state.

One embodiment provides a device wherein configuring operation of the communications module includes:

executing a protocol which accumulates transmission credits based on a battery conservation budget;

monitoring for the occurrence of a transmission trigger event based on a set of transmission rules; and

in the case that a transmission trigger event is observed, providing a transmission in response to the transmission trigger event in the case that there is sufficient transmission credit for the transmission.

One embodiment provides a device wherein the software instructions additionally configure the device to perform the following

based on input from a sensor device, recording periodic data points in a buffer;

transmitting the data points to a remote server based on a set of transmission rules, wherein the buffer is cleared following the transmission;

applying a buffer management protocol, thereby to compress the data points in the buffer in response to a set of buffer management rules.

One embodiment provides a device wherein compressing the data points is performed based on a compression algorithm that accurately maintains data representative of overall resource consumption.

One embodiment provides a device wherein the input is configured to enable selective connection to any one of a plurality of compatible sensor devices, wherein one or more of the sensor devices are configured for monitoring physical behaviour of a meter component.

One embodiment provides a device wherein plurality of compatible sensor devices includes a dual use sensor configured to monitor each of a spinning disc meter component and a flashing LED type meter component.

One embodiment provides a device wherein plurality of compatible sensor devices includes a sensor configured to monitor a contact switch type meter component.

One embodiment provides a device wherein plurality of compatible sensor devices includes a current transformer adapted to be coupled to a wire.

One embodiment provides a device wherein the device is configured to automatically detect a sensor type of a sensor coupled to the input, and execute a predefined configuration script associated with that sensor type.

One embodiment provides a method for monitoring physical behaviour of a meter component thereby to determine data representative of resource consumption, the method including:

(i) operating a sensor to take multiple observation readings for a discrete period;

(ii) performing mathematical calculations thereby to determine thresholds representative of meter component events;

(iii) based on the mathematical calculations, setting at least one threshold value that is representative of observance of a meter component event; and

(iv) configuring the sensor is to provide an interrupt each time the threshold value is crossed;

such that resource consumption data is derived from processing of interrupts after the discrete period.

One embodiment provides a method wherein the method includes configuring the sensor to provide one or more readings in response to the threshold value being crossed, thereby to determine whether (i) to (iv) should be repeated for re-calibration.

One embodiment provides a method wherein (i) to (iv) are repeated periodically One embodiment provides a monitoring device configured to monitor a physical meter, the device including:

(i) a microprocessor configured to execute software instructions;

(ii) a communications module configured to communicate with a remote server device; and

(ii) an input port configured to enable selective connection to any of a plurality of compatible sensor devices, wherein one or more of the sensor devices are configured for monitoring physical behaviour of a meter component.

One embodiment provides a method for operating a device that is configured to monitor a physical meter, wherein the device includes a sensor configured to monitor physical behaviour of a meter component, the method including:

cyclically transitioning the sensor between an active state and an inactive state based on an activation cycle, wherein the activation cycle defines:

(i) a time period for which the sensor is in an active state; and

(ii) a time period for which the sensor is in an inactive state;

selectively modifying the activation cycle based on a power management protocol.

One embodiment provides a method for operating a device that is configured to monitor a physical meter, wherein the device includes a communications module configured to communicate data indicative of meter activity to a remote server device, the method including:

configuring the device to enter an active communications state based on a set of transmission rules, wherein the device is configured to transmit data to the remote server when in the active communications state; and

maintaining the communications module in an inactive state when not in the active communications state.

One embodiment provides a method for operating a device that is configured to monitor a physical meter, wherein the device includes a communications module configured to communicate data indicative of meter activity to a remote server device, the method including:

based on input from a sensor device, recording periodic data points in a buffer;

transmitting the data points to a remote server based on a set of transmission rules, wherein the buffer is cleared following the transmission;

applying a buffer management protocol, thereby to compress the data points in the buffer in response to a set of buffer management rules.

One embodiment provides a method for enabling configuration of a monitoring device that observes a physical meter component, the method including:

receiving, from a mobile device, data indicative related to the configuration;

providing a signal over a network thereby to cause the monitoring device to perform a function observable by the mobile device; and

receiving, from the mobile device, data indicative of observation of the performed function.

One embodiment provides a computer implemented method for encouraging resource consumption behaviour, the method including:

defining a desired behaviour;

providing a signal thereby to configure a plurality of client devices to provide, via respective instances of a software application, data indicative of a behavioural instruction associated with the desired behaviour, wherein each client device is associated with a user account, and wherein each user account is associated with a utility meter; and

for a given one of the user accounts, thereby to determine whether performance conditions associated with the behavioural instruction have been satisfied.

One embodiment provides a computer implemented method for supporting analysis of resource meter monitoring data, the method including:

analysing resource meter monitoring data, wherein the data is indicative of resource consumption as a function of time for a meter associated with a user account;

identifying data indicative pattern deviation in resource consumption;

determining that the pattern deviation in resource consumption is not associated with a known resource consumption element for that user account;

causing a client device associated with the user account to display an interface for receiving input from a user, wherein the input is indicative of a specified resource consumption element; and

determining that the pattern deviation in resource consumption is attributable to the specific resource consumption element.

One embodiment provides a computer implemented method for displaying resource consumption data to users, the method including:

maintaining access to utility consumption usage for a plurality of utility meters, wherein each utility meter is associated with a user account;

providing data to a client device associated with a given one of the user accounts, wherein the data configures a software application executing at that client device to display, via a graphical interface, data representing a defined aspect of resource consumption associated with the user account relative to the same defined aspect of resource consumption associated with one or more further user accounts.

One embodiment provides a computer implemented method for displaying resource consumption data to users, the method including:

maintaining access to utility consumption usage for a plurality of utility meters, wherein each utility meter is associated with a user account;

for a given user, providing data to a client device associated with a given one of the user accounts, wherein the data configures a software application executing at that client device to display, via a graphical interface, data representing:

(i) data indicative of a cost associated with resource usage based on a current utility provider; and

(ii) data indicative of a cost associated with resource usage based on charges associated with one or more further utility providers;

receiving, from the client device, a request to change to a selected one of the one or more further utility providers; and

providing a signal thereby to cause the user to be changed to the selected one of the one or more further utility providers.

One embodiment provides a computer implemented method for enabling monitoring of a human behaviour based on resource consumption, the method including:

maintaining access to utility consumption usage for a plurality of utility meters, wherein each utility meter is associated with a user account;

for a first user account, monitoring utility consumption data, thereby to determine daily routine data; and

in the case that a threshold deviation from the daily routine data is observed, providing a notification to a second user who is subscribed to monitor the first user.

One embodiment provides a computer implemented method determining a safety rating, the method including:

maintaining access to utility consumption usage for a plurality of utility meters, wherein each utility meter is associated with a user account;

for a first user account, monitoring utility consumption data, thereby to determine whether a predefined unsafe practice is observed; and

updating a safety rating associated with the user based on observance of a predefined unsafe practice.

One embodiment provides a computer program product for performing a method as described herein.

One embodiment provides a non-transitive carrier medium for carrying computer executable code that, when executed on a processor, causes the processor to perform a method as described herein.

One embodiment provides a system configured for performing a method as described herein.

Reference throughout this specification to “one embodiment”, “some embodiments” or “an embodiment” means that a particular feature, structure or characteristic described in connection with the embodiment is included in at least one embodiment of the present invention. Thus, appearances of the phrases “in one embodiment”, “in some embodiments” or “in an embodiment” in various places throughout this specification are not necessarily all referring to the same embodiment, but may. Furthermore, the particular features, structures or characteristics may be combined in any suitable manner, as would be apparent to one of ordinary skill in the art from this disclosure, in one or more embodiments.

As used herein, unless otherwise specified the use of the ordinal adjectives “first”, “second”, “third”, etc., to describe a common object, merely indicate that different instances of like objects are being referred to, and are not intended to imply that the objects so described must be in a given sequence, either temporally, spatially, in ranking, or in any other manner.

In the claims below and the description herein, any one of the terms comprising, comprised of or which comprises is an open term that means including at least the elements/features that follow, but not excluding others. Thus, the term comprising, when used in the claims, should not be interpreted as being limitative to the means or elements or steps listed thereafter. For example, the scope of the expression a device comprising A and B should not be limited to devices consisting only of elements A and B. Any one of the terms including or which includes or that includes as used herein is also an open term that also means including at least the elements/features that follow the term, but not excluding others. Thus, including is synonymous with and means comprising.

As used herein, the term “exemplary” is used in the sense of providing examples, as opposed to indicating quality. That is, an “exemplary embodiment” is an embodiment provided as an example, as opposed to necessarily being an embodiment of exemplary quality.

### BRIEF DESCRIPTION OF THE DRAWINGS

Embodiments of the invention will now be described, by way of example only, with reference to the accompanying drawings in which:

FIG. 1A schematically illustrates a framework according to one embodiment, including a networked meter monitoring device.

FIG. 1B schematically illustrates a networked meter monitoring device configured to monitor an example electricity meter, being a disc-type electricity meter.

FIG. 2 illustrates a method according to one embodiment.

FIG. 3 illustrates a client-server framework leveraged by various embodiments.

FIG. 4A illustrates an exemplary plot of sensed data from a flashing LED meter component.

FIG. 4B illustrates an exemplary plot of sensed data from a spinning disc meter component.

FIG. 4C illustrates an exemplary plot of sensed data from a CT.

FIG. 5A and FIG. 5B illustrate a beacon device according to one embodiment.

FIG. 5C and FIG. 5D illustrate a sensor according to one embodiment.

FIG. 5E and FIG. 5F illustrate a mountain bracket according to one embodiment configured to receive the sensor of FIG. 5A.

FIG. 5F and FIG. 5H illustrate a further mountain bracket according to one embodiment, also configured to receive the sensor of FIG. 5A.

FIG. 5I and FIG. 5J illustrate a lens component to assist in mounting bracket alignment.

### DETAILED DESCRIPTION

Described herein are frameworks and methodologies configured to enable monitoring and processing of meter data. Embodiments of the invention have been particularly developed for application in the contexts of enabling real-time monitoring of meter data, for example electrical meters, and the provision of functionality of users based on processing of monitored data. While some embodiments will be described herein with particular reference to that application, it will be appreciated that the invention is not limited to such a field of use, and is applicable in broader contexts.

In overview, technologies described herein are focused on the reading of meters, such as utility meters, substantially in real time, and utilisation of substantially real time consumption data thereby to provide information to end users (for example via mobile apps). In this regard, some embodiments provide hardware devices configured to read existing meters, for example using optically-based sensing techniques. Other embodiments provide methodologies and software operable to manage meter reading (for example using optically-based sensing techniques) and networked communications in a power-efficient manner thereby to enable conservation of battery life in a meter monitoring device. Further embodiments provide methodologies and software configured to make use of meter data for various applications, including the likes of: behaviour management based on energy cost savings, in-home monitoring, utility billing, and so on.

The disclosure herein is currently geared toward electricity meter monitoring, however it should be appreciated that it can be similarly translated to water, gas, oil or any other metered utility. Additionally, when optimizing and having multiple data streams can be combined to additionally optimize on resource consumption.

### Exemplary Framework

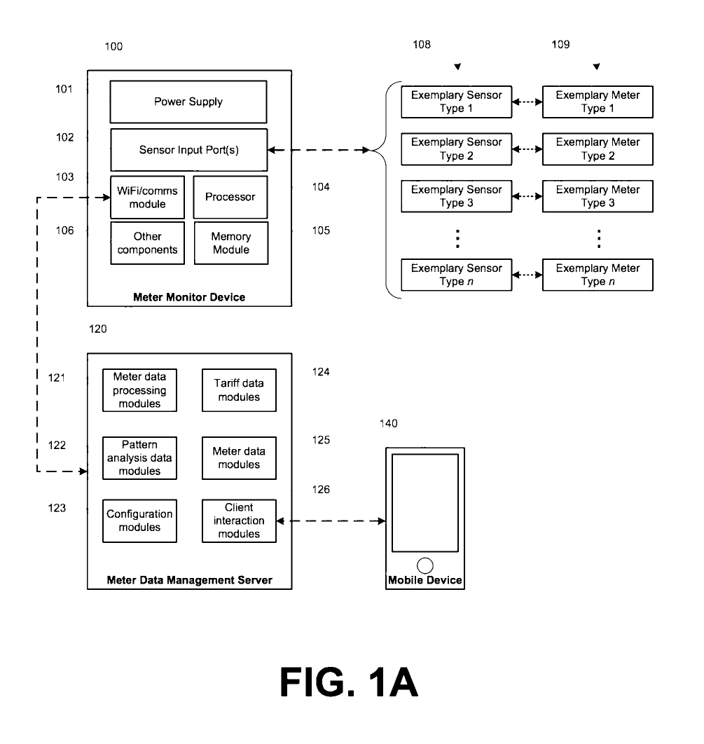

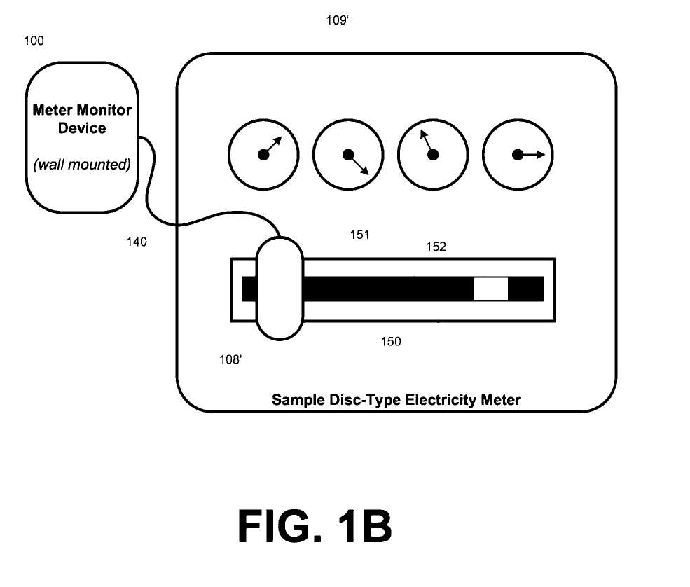

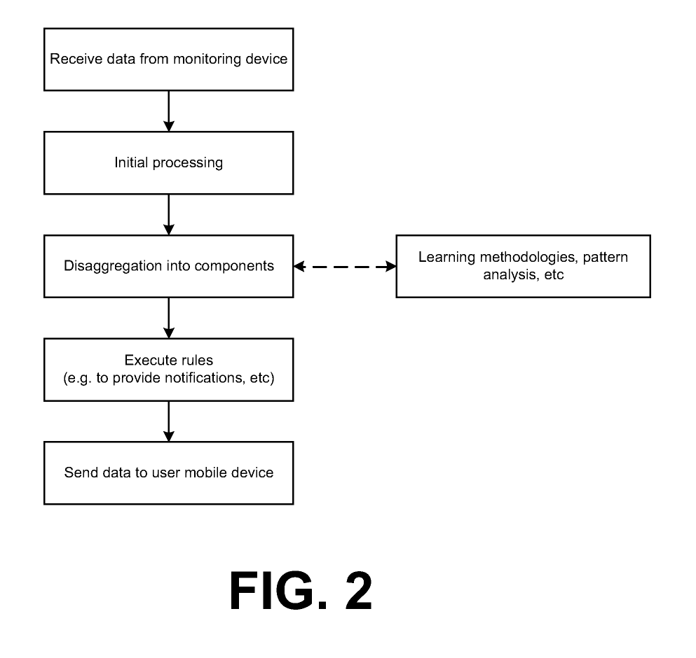

FIG. 1A illustrates a framework according to one embodiment. In overview, a plurality of meter monitor devices, also referred to herein as “beacons” or “beacon devices”, such as device 100, are installed at client sites. The use of the term “beacon” is not intended to confer an ordinary dictionary meaning; rather the term is used to describe a particular category of hardware device having functionality and/or purpose based on disclosure provided herein. Device 100 is configured to be mounted to, or proximal, an existing meter device. Although only exemplary device 100 is shown, various other devices similar to device 100 may be used in the framework. Additionally, the framework may include integrated monitoring devices whereby components and/or functionality associated with device 100 are integrated into a meter device (whereas device 100 is configured for aftermarket installation).

Device 100 includes a power supply 100, which may include one or more rechargeable or non-rechargeable batteries. Power supply 100 is preferably self-contained, thereby to enable installation of device 100 in locations where there is no external power source available. As described below, device 100 is configured to implement various power management protocols thereby to manage power consumption, hence preserving battery life.

Device 100 includes one or more sensor input ports 102, which enable the connection of sensors 108. Device 100 is configured to connect to a range of different sensors 108, thereby to enable integration with a range of existing meters 109 (for example “flashing light” meters, “spinning disc” meters, and so on). In practice, a user installs a device 100, and connects a sensor 108 appropriate for the relevant meter 109. Subject to an installation and configuration process, device 100 is then able to read meter 109 in real time via sensor 108.

Device 100 includes a microprocessor 104, which is configured to execute software instructions maintained on a memory module 105. Memory module 105 additionally is configured to maintain a buffer of monitored data. Data monitored by device 100 is communicated via a communications module 103 (which may be a WiFi module, cellular communications module, Bluetooth module, Zigbee module, or other form of networked communications enabling module) to a meter data management server 120. Data is able to be communicated in real time. However, in some embodiments power management protocols are implemented such that redundant data is not transmitted, thereby reducing the amount of data transmitted, and hence reducing power consumption by communications module 103.

The communications module may connect to the Internet via a number of methods, including via connection to a local router (optionally using an antenna component) that is connected to the Internet, connection to a proximal device that connected to the Internet via a cellular network, via cellular networks directly, and so on. In some embodiments the communications module operates based on a custom wired or wireless protocol.

Server 120 is configured to receive data (directly or indirectly) from a plurality of meter monitor devices, which may include devices such as device 100 and/or other devices that are configured to provide data indicative of resource consumption. Although, for the present purposes, it is generally assumed that the data is derived from external monitoring of a physical meter component, substantially any device that provides medium to high resolution data which is able to be analysed as substantially real time data could be used.

In the example of FIG. 1A, server 120 includes meter data processing modules 121. These modules are configured to, for a given stream of data received from a monitoring device convert that data into a predetermined form for the purpose of analysis. For example, this may include smoothing, normalisation, cleaning, and/or other data processing techniques.

Pattern analysis data modules 122 are configured to monitor patterns in the processed meter data. For example, this in broad terms includes disaggregating data based on known or predicted patterns thereby to preferably isolate individual resource consumption elements or effects. For example, common appliances such as refrigerators, dishwashers, air conditioners, and the like, display certain patterns in the context of electricity consumption. Pattern analysis modules are configured to identify variations in resource utilisation based on such disaggregation, thereby to allow client interaction modules 126 to provide data to user mobile devices.

Configuration modules 123 and meter data modules 125 enable configuration of meter monitoring devices for particular meters. For example, configuration modules 123 provide algorithms and the like thereby to enable the performance of a configuration process, whereas meter data modules 125 include data indicative of individual meter types, thereby to enable determination of an appropriate configuration proves for a given client installation.

It will be appreciated that, in FIG. 1A, server 120 is illustrates in a relatively basic and functional form. Furthermore, it should be appreciated that specific algorithms and processes for enabling data processing and disaggregation fall beyond the scope of the present specification. A significant amount of publicly available research material is available relating to methods for disaggregating and processing data indicative of resource consumption thereby to make predictions as to appliances and the like that are responsible for that consumption.

In some embodiments, a resource consumption meter defines a metering point. That is, an electrical line is directly monitored for example via a CT or a power metering circuit. This does not have to be a pre existing meter. In some embodiments a sensor includes a protocol translator directly communicating with a meter with a known protocol, for example over a RS485 connection.

FIG. 1B schematically illustrates networked meter monitoring device 100 configured to monitor an example electricity meter, being a disc-type electricity meter 109′. Meter 109′ includes a transparent window 150 behind which a disc component 151 is visible. Disc component 151 rotates (about a vertical axis in this example) at a rate proportional to a monitored rate of electricity consumption. A peripheral reflective portion 152 assists in visually identifying a rate at which rotation is occurring. In other examples a non-reflective portion is used; the core concept is that there is a visually distinguishable peripheral portion of the disc. That visually distinguishable portion has different reflectance properties to the remainder of the periphery. Device 100 in this example is coupled, via a cord 140, to a sensor 108′, which is a IR proximity/reflectance sensor. Such a sensor is capable of externally physically observing the behaviour of rotating disc 151 based on different reflectivity between peripheral portion 152 and the remainder of the periphery of disc 152.

In the illustrated embodiment, device 100 is mounted to a wall, although various forms of mountain brackets and mounting locations may be used. For instance, a mounting location is optionally selected based on convenience and wireless connectivity. Sensor 108′ is mounted to meter 109′ in a suitable location for monitoring disc 151. This preferably uses a mountain arrangement that allows for fine-tuning, for example 3M™ Dual Lock™ or the like (trademarks are used for the purpose of example only, and do not imply and permission, affiliation, or the like). Various visual assist features are preferably provided to assist a user appropriately mount and align sensor 108′.

FIG. 1B is one example of a meter and sensor combination only. Various other combinations are described below, and it will be recognised how similar mountain arrangements are implemented in practice.

An infrared (IR) proximity/reflectance sensor such as sensor 108′ is also configurable to monitor flashing light type meters (i.e. meters that include a LED light that cycles between an on and off state proportionally to resource consumption). In some embodiments a common form of sensor is provide for both disc and light type sensors, and operation of the sensor configured depending on the actual use (for example IR transmitting is not required when monitoring light emission).

### Overview of Power Management Functionalities

Various embodiments include, or make use of, battery-powered monitoring devices. In such devices, there is a need to operate electrical components in a particularly efficient manner, so as to preserve battery life. It will be appreciated that meter monitoring is in effect a continuous process, and it would be onerous (or at least create unwanted inconvenience) to expect users to replace/recharge batteries every few days/weeks/months. Accordingly, the present disclosure details technology which is used in embodiments thereby to preserve battery life. There are three main aspects to this power management technology:
Sensor activation/deactivation. For example, a given sensor is operated based on cyclical transition between an active state and in inactive state, thereby to limit power consumption by containing the amount of time for which the sensor is in the active state.
Communications module power management. A typical communications module (such as a WiFi module) might draw in the order of 400 mA when in a transmit mode, and 100 mA in a receive mode. Approaches described herein serve to contain the amount of time these modes are used, such that the communications module may be otherwise deactivated (or run in a standby mode), thereby to bring average current usage down to under 3 mA (or preferably less than 1 mA) averaged over an extended period (for example over the course of 24 hours).
Memory buffer management. A device has a limited memory buffer, and there are advantages associated in using specific protocols to manage that buffer thereby to, by way of example, (i) assist in containing communications module utilisation; and (ii) manage data resolution in an appropriate manner.

It will be appreciated that memory buffer management has application beyond pure power management, for example in the context of transmission overhead management (which is relevant in situations where data transmission incurs costs).

Power savings protocols may also be implemented for other non-critical functionalities, such as a temperature module, LED brightness, and the like. For example LEDs maybe flashed shorter, less often, or less strong as the battery power decreases (for example upon it decreasing below a threshold level, or based on other observed batter-related conditions), or at different times in the life of the module. In some embodiments power management is performed/controlled in response to temperature (for example based on predicted temperature derived from factors including geographic location, time of day, time of year, weather knowledge, and so on), noting that battery performance is affected by temperature. Various other input may also be used to vary power management functionalities, such as knowledge of battery types (e.g. brand and model), which enable prediction of voltage over a battery power source's lifespan (for instance in relation to high current draw vs low current draw).

In some embodiments a user is enabled to provide input thereby to indirectly control power management functionalities based on high-level user preferences. For example, a user is provided a user interface component that enables selection of reporting options and/or functionalities, and opting in/out would affect power management functionalities (and hence battery life). In one embodiment the user interface provides a sliding controller which enables a user to balance between data quality and battery life.

In some embodiments a user is enabled to set a minimum desired battery lifespan, and power management functionalities are defined based on algorithms which seek to reach the defined goal. For example, in some embodiments such an algorithm sets a time-based budget for performing certain actions (for example “maximum 1 per minute”, which is optionally based upon an achievable number over the desired battery lifespan period) such that actions are performed in a budgeted manner to conserve battery life in accordance with the user-set desired battery lifespan. Exemplary power management approaches are described below. Although these are predominately described in isolation, it will be appreciated that preferred embodiments use all three.

### Power Management Via Sensor Activation Cycle

Some embodiments provide a method for operating a device that is configured to monitor a physical meter, wherein the device includes a sensor configured to monitor physical behaviour of a meter component, the method including: cyclically transitioning the sensor between an active state and an inactive state based on an activation cycle; and selectively modifying the activation cycle based on a power management protocol.

The activation cycle defines a time period for which the sensor is in an active state (i.e. a state in which the sensor monitors activity of a meter component) and a time period for which the sensor is in an inactive state (for example a low-power mode, or a state in which no power is supplied to the sensor).

In some embodiments, the activation cycle is determined by reference to an estimated maximum amount of electricity consumption change between cycles, and adjust the on off time accordingly. The general underlying principle that, using a threshold range for “expected” values for readings are made based on the activation cycle the device is enabled to determine that there may have been change in load, for example due to the activation of an electrical device or a change in a device's operation.

In a similar respect, in some embodiments the activation cycle defines a time period for which the sensor is in an active state (for example the active state is one of high power consumption such as communicating values) and a time period for which the sensor is in an inactive state (i.e. lower power for example where the sensor is simply reading values and comparing to threshold(s) setting an interrupt if a threshold is crossed).

In overview, some embodiments implement a power management protocol based on an algorithm which includes: (i) performing signal analysis over a plurality of cycles; (ii) performing analysis of sensed data over that plurality of cycles thereby to determine signal parameters, including (a) a signal component representative of load; (b) an activation cycle; and (c) threshold values, for example a minimum threshold range and a maximum threshold range; and (iii) based on a predefined protocol, repeating (i) and (ii) in response to an observed level of deviation from the threshold. In response to determining that there may have been a change in load, the device selectively repeats the step of monitoring a plurality of cycles, and set new thresholds accordingly.

In some cases, the device makes a determination that deviation from the threshold is result of factors other than a change in load. For example, as discussed further below, a light-based sensor may record increased light intensity due to ambient light. Some embodiments provide technology configured to enable determination of whether a change in value is due to ambient light or a monitored LED (for example based on light color analysis).

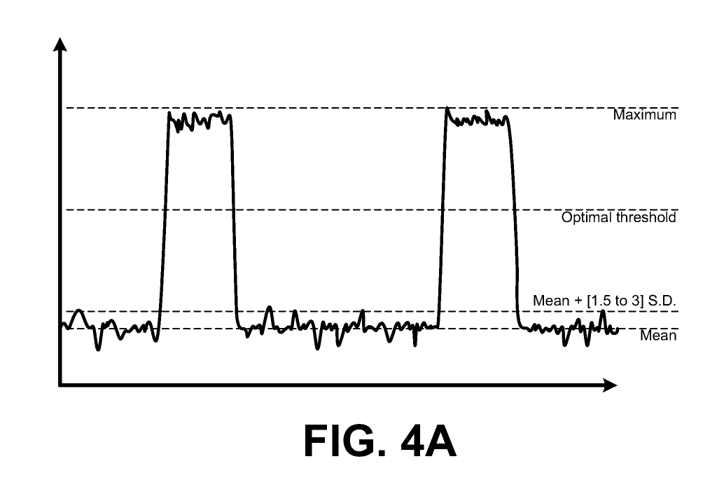

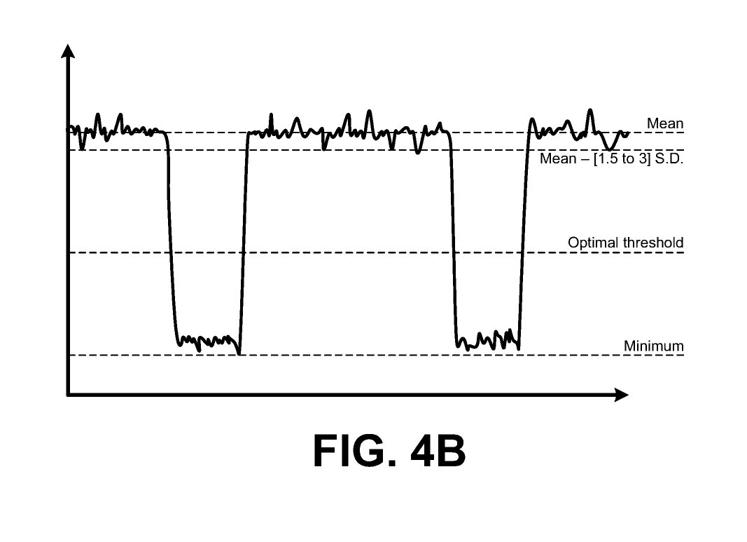

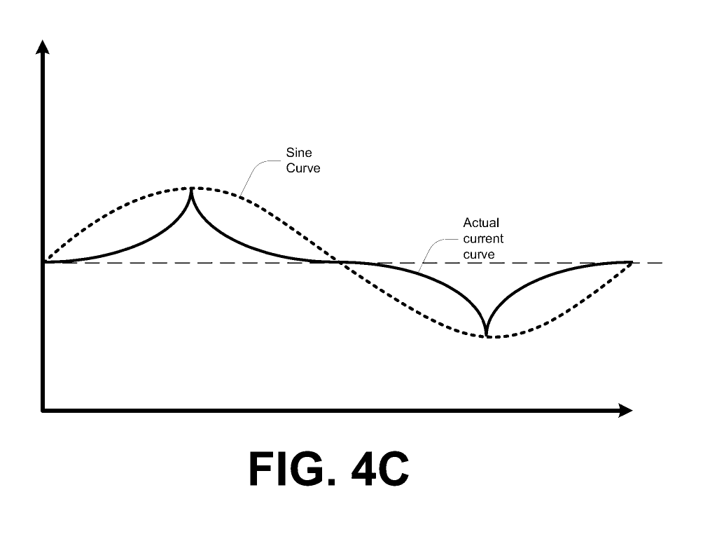

An exemplary method for determining thresholds illustrated by reference to FIG. 4A and FIG. 4B. FIG. 4A and FIG. 4B each illustrate an exemplary portion of signal from a sensor (which is representative only, and not intended to necessarily accurately represent a physically observed signal). FIG. 4A is a sensor configured to monitor light from a flashing LED, FIG. 4B is a sensor configured to perform IR reflectance sensing for a spinning disc meter (which includes a reflective periphery having a low-reflectance mark). A cycle is defined, in this case, by a period during which the disc mark passes in front of the sensor, followed by a period for which the disc mark is not in front of the sensor. The resulting sensor data shows period where disc mark is observed, and period where disc mark is not observed. However, light intensity readings are not a smooth curve due to various factors.

The frequency of disc observation/non-observation is representative of load, with a higher frequency indicating higher electricity consumption. Hence, an activation cycle is defined thereby to monitor for changes in that frequency. For example, a change may be evidenced by observing a value that is not associated with disc activation at a point in time where the determined frequency would have predicted a value associated with disc activation.

Given that light intensity readings representative of disc activation are not constant, a threshold range is determined. Determining a threshold range for a disc state change includes determining an average intensity reading over the multiple cycles, a standard deviation from the average over that cycle and tracking high and low points over that range and defining a threshold range relative to those numbers. For example, the range may be defined by reference to statistical analysis, for example based on two standard deviations from the average. This is shown (not to scale) in FIG. 4A and FIG. 4B. That is the threshold could be determined as the halfway between the 2 standard deviations below the average and the min. (As the LEDs data is inverted from the discs, an LED threshold may be determined in a similar way taking the inversion into account. For example the threshold could be determined as halfway between 2 standard deviations above the average and the max.) (1.5 to 3 standard deviations off the average tend to work best.) Reading the values are higher power activities where as looking for a threshold is a low power activity. When thresholds are crossed, it could trigger readings to, for example check the color of the LED or read the background level.

Based on analysis of cycles such as those shown in FIG. 4A (the number of observed cycles varies between embodiment), the device determines a load value representative of electricity consumption, threshold ranges, and an activation cycle for the sensor. Then, sensor readings are performed in accordance with the activation cycle until a rule is triggered. Such a rule may be based upon factors such as: (i) a deviation from an expected threshold range value; (ii) successive deviations from an expected threshold range value; (iii) a predefined time period elapsing without a trigger event. Various other rules may also be defined.

In some embodiments, a sensor is used which is relatively low power for monitoring, but high power for transmitting values. One embodiment, suited to that form of sensor, provides method including: (i) taking multiple readings, for example at high resolution, over a plurality of cycles; (ii) determining the signal curve from the readings; (iii) performing mathematical calculations to determine thresholds and the like; and (iv) setting a threshold value, such that the sensor is configured to provide an interrupt each time the threshold value is crossed. In some embodiments the sensor is additionally configured to perform further action upon the threshold being crossed, such as providing one or more readings, or providing color information (in the case of a LED meter). These are optionally used to check validity of an interrupt.

FIG. 4C is provided as context to an exemplary method for determining power using a CT. In overview, a CT reports on current. Power is calculated by integrating a current curve. However, a current curve is not always a regular form of curve (such as a sine wave). FIG. 4C illustrates an exemplary current curve, and a sine curve. One embodiment provides a method for processing a CT signal including: (i) reading the signal at high resolution for a predetermined period (e.g. a threshold number of cycles; (ii) determining curve characteristics (for example a difference with respect to a sine curve); (iii) determining per-cycle power based on integration of a curve (for example by defining a percentage adjustment of a sine curve integration value based on a difference between the actual curve and a sine curve); and (iv) subsequently reporting only on max and/or min events. This provides ongoing low power monitoring (as max/min reporting replaces high resolution monitoring). The method is preferably repeated periodically, for example based on time (e.g. once per second) or based on the passing of a defined number of cycles. In some cases the method is repeated on a trigger, for example a variation in max/min values.

In some embodiments, the power management protocol is configured to modify the activation cycle responsive to variations in an observed meter activity pattern. For example, an automated process operates thereby to determine a maximum expected deviation in load (and hence change in meter activity) over a given cycle, optionally determined based on historical monitoring. This, from a practical perspective, in some cases correlates to a maximum number of electrical devices that are predicted to be activated in a household over a given cycle. For example, the activation cycle is tailored based on a threshold anticipated variation in load as a function of time (for example a maximum anticipated variation in load).

The power management protocol management protocol may, through reasonable approximation, determine a “like worst-case minimum period” before the next power indication (for example a power indication may be represented by identification of a identifier mark on a spinning disc type meter component) using expected behavior. This, in some embodiments, is provided via a separate prediction engine, which is configured to compensate for known patterns such as the cycling of a known refrigerator, the progression of a dishwasher program for a known dishwasher, etc, and also for likely known electrical elements of the system. Information relating to electrical equipment in a given dwelling is in some embodiments inputted by a user (for example during a manual configuration phase), and is in some embodiments inferred by an algorithm. In that context, “inferred” in some embodiments includes tracking power over a period of time, and observing the change of power demand at any particular time.

There are absolute bounds of the electrical elements; for example, while a meter in a house may allow 100 A current, most houses only have 15 A-20 A on one circuit capping the largest appliance. Further, if one is tracking switched loads, one is likely able to further narrow the maximum appliances. It is worth noting that processing may account for group loads, which are generally turned on simultaneously, such as lights in a room controlled from one switch, or even multiple switches from the same panel which are generally switched at once as single switched load.

By estimating when most likely the next indication is expected, and what switched loads available, one can estimate the time period within which an appliance may be turned on and off. For example, the dishwasher and dryer are unlikely to be turned on within 10 seconds, however the clothes washer and dryer are much more likely to be turned on within close proximity in time. It is also unlikely the space heater and air conditioner will be turned on at the same time.

In some embodiments an activation cycle is defined such that the “off” period is shortened by a safety margin to adjust for errors in calculation.

Given that sensor activation cycle determination is inherently based on a certain number of predictions/assumptions of future events, there is always a possibility of errors/inaccuracies. Accordingly, in some embodiments a sanity check is performed periodically, to allow efficient error recovery. This include, in some embodiments, operating the sensor in its active state a full cycle (or near full cycle, for example off only for a minimal amount of time based on meter limits) on a defined periodic basis. This could also be triggered on anomaly event, for example, like if the observed power consumption drops by an amount that is inconsistent with the configuration of the house.

Another recovery mechanism, which is provided in some embodiments, includes turning the sensor on and off several times during a single anticipated cycle period. This enables the device to observe several potential failure mechanisms. These are referred to as “redundant activations”, being activations performed to validate whether activations defined based on predictions remain effective.

As an example, one mode of failure is observed where the next indication arrives sooner than expected by small amount (i.e. the “off” time interval was slightly too long). In the case that the sensor is off during an indication, the measured usage will be less than the actual usage (typically half, although it could be ⅓ or worse depending on the extent of interval length over-estimate, or if the issue compounds). Such a failure could (and is likely to) repeat, as the inputs to the power management system are corrupted.

The repetition, however, is likely to occur at certain fractions of intervals. Accordingly, a redundant activation is performed at each X/Y. So if the expected indication is at X, if there is a failure of this sort it is likely to be observed at X/2 or X/3. Some embodiments observe these as the most common possible failure points. More generally, an indication could occur at X/Y for all Y for the most common Y (with “Y” being 1+ the number of missed indications). For example, it could be X/Y where Y is a prime number, thereby to enable correction correct in less than or equal to the number of prime factors of the issue.

Some embodiments apply an approach including activating the sensor device to check for intervals that wouldn't be caught by the difference between the minimum expected time for an indication and the expected time for an indication. This is optionally performed for all Y (could be restricted for common or prime Y) for which (Y−1)/Y is less than (min expected period)/expected period.

The above reduced interval activation cycles assume that generally, the indications are often on regular interval (within some error) and so while the correction is ineffective on an interval where there is change, there are enough intervals where there is little change the correction will occur relatively quickly). Another mechanism is to systematically, or randomly turn the sensor on for a short period of time over the off interval. For instance, a first cycle check for being off by 1:2, a next cycle for 3:1, and so on. Alternately, a first cycle runs a redundant activation 0-10% of the anticipated cycle, 10%-20% for the next anticipated cycle, and so on. This is optionally weighted based on anticipated likelihood of the different failure modes (for example to check at 1:2 for half of all redundant activations, at 1:3¼ of the time, 1:5⅛th the time, etc.

The power management protocol is in some embodiments configured to modify the activation cycle responsive to a time of day. For example, based on analysis of historical data, the activation cycle may be shorter or longer at different times of day (for example noting that power usage during the evening is typically quite consistent, as people sleep).

In some embodiments the monitoring device maintains software instructions indicative of a local power management protocol, whilst the server device maintains software instructions indicative of a server-side power management protocol. These operate in conjunction with one another; the server is configured to modify the local power management protocol responsive to the server-side power management protocol based on processing of data received from the monitoring device.

In some embodiments, where a “smart current transformer” (CT) is used, there are 3 general power levels: high power, low power, inactive. Operating in the high power mode includes high resolution reading of the sensor, and analysing the data directly. Operating in the low power mode includes executing a process that includes identifying specific “fingerprints” in sensed data. The inactive mode configures the sensor to be powered off or in a standby state. Low power and high power modes in some embodiments vary in power by adjusting resolution settings in the active CT module. For example: off/standby=inactive; pre-processed reading such as max/min reading=low power; constantly reading=high power.

As a relevant principle, CTs indirectly measure power by measuring current. Since voltage is relatively stable, current can be used to derive an estimate of power. There are, however, challenges where a phase shift exists between current and voltage curves. However, while power cannot be directly accounted for perfectly, current does provide a fingerprint for detecting different devices and when they are using power, as well as an approximation of how much power they are using. This fingerprint is in some embodiments correlated to power usage, where the actual power usage of those appliances are known through direct measurement or off same or equivalent devices. This in some cases involves additional processing, including line voltages might being backed out, and utilisation of power factor and/or phase shift for some devices). In any event, given that CT data is useful there are many ways to get CT data. Power consumption is a result of running the CT and fetching the data from the sensor. Many techniques can be used, often in combination, varying under given factors like load, time of day, etc. (determined on board or by a server device). There can be a lot of CT data so averaging (integrating) over some interval can reduce the amount of data needing to be sent to the server. Selective averaging is applied in some embodiments to reduce a number of points in data points. So, for example, collecting data for 1/10th of s second every second is a first stage to reduce power consumption. By only looking at the max and min value over a cycle or series of cycles (using min/max functions in the sensor) there is a further reduction in power by reducing the number of data fetch actions. The Min and Max will give a different reading than straight current, but remains acceptably consistent with a detection algorithm (the triggers are in some embodiments slightly different). The value here could be an equivalent value as current assuming the current is a sine wave.

To adjust these readings to better match actual current, the ratio of min/max measurement to actual current is preferably determined by reading the current rapidly for a cycle, or a set of cycles. A correlation is determined between the max/min and the trace, and that correlation adjustment is applied to the max/min until the adjustment is determined again many cycles later. This correlation method is preferably repeated on a defined time interval, or as a result of a trigger (for example where the max/min changes by a defined threshold). Sending this correlation or the current curve directly to the server in some cases also assists in appliance detection (as it provides an additional variable on which to perform analysis).

In some embodiments the processing outlined above is performed in the CT and communicated to the beacon on timed on a periodic or interrupted basis. Additionally, a sensor component that receives/fetches data from the CT can be turned off/standby while not receiving/fetching data from the CT.

### Power Management Via Operation of Communications Module

Some embodiments provide a method for operating a device that is configured to monitor a physical meter, wherein the device includes a communications module configured to communicate data indicative of meter activity to a remote server device, the method including: configuring the device to enter an active communications state based on a set of transmission rules, wherein the device is configured to transmit data to the remote server when in the active communications state; and maintaining the communications module in an inactive state when not in the active communications state.

In some embodiments, the active communications state includes a transmission period and a receiving period (corresponding to operating the communications module in a transmit and receive mode). In one embodiment the receive mode is maintained for a predefined period pending a transmission confirmation message from the server. The transmission confirmation message may include a flag to indicate that the server will transmit additional data, and the device is configured to maintain the communications module in the receive mode responsive to such a flag.

In some embodiments the remote server is configured to selectively modify the transmission rules. That is, a set of rules are stored in memory at the monitoring device, and executed by the device. The remote server executes a process that, based on monitoring of meter activity derived data, selectively defines modified rules, and transmits data indicative of those to the monitoring device thereby to update the rules stored in local memory.

The transmission rules preferably include a plurality of interrelated rules, which may be prioritised based on a predefined protocol. The rules preferably include one or more of the following:
A rule to transmit at predefined intervals. The predetermined interval may be modified subject to rules defined locally, or based upon direction from the server. For example, relatively shorter intervals are applied at certain times of day.
Rules to transmit in response to deviation from expected meter activity. For example the expected meter activity may represent a substantially constant load. In some cases the expected meter activity represents a defined load pattern (which may be inferred from monitoring a set of load pattern indicators.
A rule to transmit responsive to memory buffer conditions. Preferably, this is configured to prevent a buffer from filling (which might be achieved by ordering transmission at a predefined buffer level that allows for a delay between instructing transmission and achieving transmission).
A rule to transmit on responsive to time-of-day specific schedule.
Rules to transmit based on a schedule that is influenced by external data sources, including any one or more of the following: calendar or schedule information for a user; public holiday and events data; user behaviour data; and location data received for a mobile device (for example a device carried by a home owner, thereby to indicate whether he/she is home or away from home).

In some embodiments, one or more rules are applied in response to user input. For example, a user selects desired operational parameters, which in some cases balance detail in reporting and battery conservation.

In some embodiments, options include an “ultra low power mode”, which provides minimal instant reporting upon observed changes, thereby to maximize battery life (this is useful for users who do not want to switch batteries often, and are disinterested in real-time reporting. Another option in some embodiments is a “stealth mode” which transmits at random intervals so someone sniffing packets nearby can't tell usage by when packets are being sent (a related optional feature adds false data to be ignored by server so they couldn't tell by size of packets). Another option, in some embodiments, is an “energy audit mode”, which is provided for devices with extra local memory, and which transmit only on button press. For example, this is useful where an energy auditor travelling manually causes download of data stored in the local memory, and/or where devices only have an internet connection when a portable networked device is brought into proximity.

In some embodiments, power management power management via operation of communications module includes determining whether to transmit data based on analysis of load patterns.

In relation to load patterns, various electrical devices may display a relatively constant load pattern, for example a fridge, heating system, or the like. These patterns typically include a series of peaks and troughs. However, pattern frequencies are generally not aligned. Accordingly, data representing meter activity represents an aggregation of a plurality of these patterns. Monitoring of patterns is in some embodiments achieved without a need to disaggregate data by monitoring for load pattern indicators. For example, these may define peak value ranges, and an anticipated peak spacing range, representing an aggregation of expected load patterns.

Some embodiments make use of an arrangement whereby a decision to transmit is triggered based on deviation from an expectation in load pattern. For example, when there is a constant load, the server may expect around that constant load (say 1.2-1.4 kW) to continue, at night time when things are not being switched on and off. It can send this information to the processing unit. The processing unit only transmits when consumption falls outside the expectation.

Some embodiments make use of an arrangement whereby the expectation is variable based on patterns from a load. For example, a hot water heater turning on and off in the night with a constant base load may have the pattern, base load or base load plus water heater with the addition that the power consumption averages. For instance, this is represented by [(base load)*t_{off}+(base load plus water heater)*tₒₙ]/tₜₒₜₐₗ over some time interval, where t_{off} is the time spent in the off state, tₒₙ is the time spent in the on state, and tₜₒₜₐₗ is the time in both the on and off state and base load and base load plus water heater are in units of power.

Some embodiments make use of an arrangement whereby the server provides data using values in terms of data that is easy to process from the attached sensors. In particular, rather than providing instructions based upon power values, they may be based upon meter-observed values. For example, if a disc detect sensor is in use, and it is known that 1 rotation=2 Wh, it is less computationally complex (i.e. lower power) to work in seconds. In that regard, 100 Watts=rotation every 72 seconds, so a value of 100 watts+1-2 watts would be a rotation interval between about 70.5 and 73.5 seconds. Accordingly, rather than instructing a device to monitor for a power change, a change in rotation is less computationally complex.

Some embodiments make use of an arrangement which uses time of day to determine transmission rate. For example, reporting can be slowed to once every 15 minutes for a defined period corresponding to anticipated sleeping hours, buy sped to once a minute (or faster) for a defined period corresponding to an anticipated time when people get up in the morning.

Some embodiments make use of an arrangement which uses determination (or prediction) of user location information to determine transmission rate. For example, mobile device location monitoring enables determination of whether one or more persons are at a home. When someone is away from their house they may need updates only every 5 minutes where they may want every minute when they are home.

In some embodiments, transmission is controlled based on time (for example transmissions every X minutes). In other embodiments, transmission is controlled based on number of data points collected (for example transmissions after every Y data points collected). As context, transmitting every Y data points allow for inherent adjustment of reporting rate as a function of time based on energy usage. This is because when someone is using a lot of energy the data is reported faster than when they are not using minimal energy, thus saving power automatically without an time based update.

In some embodiments the device only transmits, and asks if there is any configuration data for download after it transmits, meaning that the device doesn't have to keep its receiver on all the time (only when there is “mail” waiting to be delivered).

### Power Management Via Operation of Communications Module: Transmission Protocols

Some embodiments achieve power management via operation of communications module utilizing multiple transmission protocols (for example TCP and UDP), and setting rules that define when particular transmission types are used.

Some embodiments make use of multiple transmission types (for example TCP and UDP). It will be appreciated that various transmission types can have trade-offs between data transfer reliability, power efficiency, and power consumption. These types of transmissions can be mixed to give the required data quality and responsiveness. For example, in some embodiments a protocol is defined that enables accurate power readings at a specific point in time in fine detail (for instance where it is acceptable to receive a low proportion, say 70%, of data points; the focus is to know as soon as they are available), and provide quality historical data for bill generation with less emphasis on real-time data provision. The latter is then uploaded less often (but more reliably). That data is also optionally time compressed, (for example using 15 minute intervals), to further reduce power by reducing the amount of data transmitted.

That is, when responsiveness is required, data is transmitted using a high efficiency lower quality transmission type. When high quality data is required, data is be sent using methods that are more reliable (and use more power per transmission), but less often as fewer transmissions of this type are sent, and when they are sent efficiency per data size is higher, and hence overall efficiency is improved.

By way of example, the transmission types may include UDP and TCP. The power overhead associated with setting up TCP is much greater than the power used actually sending data packets, whereas UDP has very little setup overhead however isn't as reliable as TCP. Accordingly, TCP is preferably used to reliably send periodic data (either all data, or time compressed data), whereas UDP is used to send points as soon as available (or in some cases on a time interval sending unique or redundant data).

Some embodiments utilise a lower power, but more lossy, protocol. This preferably includes sending data multiple times (i.e. redundant transfers) to increase the likelihood of data making it to the server. At the cost of memory and processing power. For example, in one embodiment UDP is used, and the device is configured to send: the last 20 min of data very often; and the last 24 hours of 15 min time compressed data every transmission on regular (for example 1 minute intervals). This provides high power efficiency, and high reliability for data that is used to determine oversell consumption.

The above approaches in some embodiments extend to use of different transmission hardware. For example, it is common for people have Bluetooth only on their phones but WiFi is always available in the house. Bluetooth is lower power than WiFi. Hence, a protocol in some embodiments configures the device to transmit high frequency data over Bluetooth when in range of a coupled Bluetooth device (which in turn transmits via the Internet), and provide low frequency data when only WiFi is available. This is in practice sensible, as a user may only care to have high speed data when they are home, since that is the time when they are using electricity and they can actually take actions to change that electricity consumption. This provides increased responsiveness when responsiveness is needed, at reduced power consumption.

### Power Management Via Operation of Communications Module: Transmission Rules

In some embodiments, transmission power is conserved by way of rules that determine in what circumstances to trigger a transmit event. For example, rules are defined thereby to trigger a transmit event in response to an identified load pattern (i.e. a load pattern having defined characteristics), and/or defined thereby to ensure reliable transmission of power consumption data relevant to overall power consumptions (for example data relevant to billing). This in some cases factors into approaches described above: overall consumption data is transmitted based on a first set of rules, which ensure reliable transmission of data covering a given period, and observation-triggered data is transmitted based on a first set of rules, which govern transmission in response to identified load patterns (and the like).

In some embodiments, rules are defined for load patterns that are identified based upon power consumption, current consumption, phase, power factor, and the like (dependent on metering type), and ranges thereof. Ranges can be defined by reference to: static values (for example a value defined for a conventional house light), values for discrete intervals of time (for example it is known that a fridge turns off at a certain rate at a certain power; the time interval changes when the door is left open, thus warranting an alert or the like); and values defined partially based on intervals of time (for example motions sensor lights that activate with 100 W+1 W for at least 2 min of time).

Additionally, in some embodiments load patterns are used in a generally opposite manner. For example, one approach is to apply a protocol that ignores all data aside from data predicted to describe activity of a set of defined known appliances. For example, this is useful in a situation where there is activity using a lot of variable electricity (for example construction/renovation work), but there was a desire to monitor for known activities of concern, such as a fridge door that is left open. A pattern of that fridge's door is determined and alerts are be triggered by the identification of that pattern, even in spite of the presence of other variable loads.

In some embodiments rules are defined in respect of specific load patterns, such that identification of specific load pattern triggers a delayed data transmission. This enables collection of additional data prior to transmission. The delay is optionally defined based upon: a number of data points; a fixed time interval; or a secondary trigger event. In some embodiments the delay is variably defined based on the size of a variation in the load pattern. In some embodiments, a defined “no-transmit” period is defined following a transmit event. In this case, transmission triggers are ignored (or alternatively delayed) until the “no-transmit” period completes.

In some embodiments, transmission rules are defined based on device parameters. For example, transmission rules are set based on buffer capacity (e.g. rules to transmit where buffer is full or nearing the full level).

In some embodiments, a transmit event occurs only in the case that (i) satisfaction of a rule results in a trigger; and (ii) conditions allowing for that transmit event to occur are satisfied. Both (i) and (ii) are in some embodiments aspects of “transmission rules”. For example, the conditions may be defined to contain the number of transmit events to with an acceptable threshold for battery life preservation. In some embodiments transmission timer is used, for example a timer that resets after reach transmit event, and some embodiments implement a base level on a deviation transmitter. Transmission triggers are optionally vetoed or delayed dependent on a predefined algorithm to conserve power consumption by accumulating transmit time as time passes.

In some embodiments, a transmission budget is defined which accumulates 1 standard transmit event every X seconds, with a “standard” transmission event being defined by reference to an estimated level of power consumption (i.e. battery power consumption). The budget is in some embodiments defined such that (i) a number of standard transmit events over a battery lifespan is estimated; and (ii) the accumulation rate is defined based on a desired battery lifespan, such that the estimated number of standard transmit events are accumulated over the desired lifespan. That is, a budgeting system is applied such that a limited number of “transmit events” are permitted over a period of time, for example an anticipated battery lifespan. The budgeting system causes an accumulation of “transmit credit” periodically. In this manner, a transmit event occurs only in the case that (i) a transmit event is triggered; and a transmit credit is available. This allows predictable battery usage over an extended period, whilst allowing irregular spacing of transmit events (with accumulation enabling more regularity in transmit events at certain times).

In some embodiments, decisions regarding whether or not to transmit based on triggering of a transmit event, in the context of a budgeting system, takes into consideration a power overhead of a given transmit event relative to a standard transmit event. For example, a given proposed transmit event may be 0.5 of a standard transmit event, or 2.5 times a standard transmit event. That is, each transmit event is effectively weighted relative to a standard event. The weighting is optionally based on any one or more of: an estimated size of transmission (for example based on packet size); by physical timer and/or given by averages and/or determined by packet size and/or by transaction; based on actual direct measurements, such as current or power (for example where a weighting is determined following a transmission). Baseline current draw is taken into consideration in some embodiments. In some embodiments transmit events are monitored thereby to define and/or optimize weightings over time. For example, events are assumed to be standard events, and re-weighted based on monitoring and comparison with standard event parameters.

In some embodiments, accumulation rates for transmit credits are defined in a dynamic manner based on external factors. For example, cold weather could reduce the effectiveness of a battery, and that is in some embodiments accounted for by tying an accumulation rate to temperature (for example to allow a first number of transmits for a day in a first known/predicted temperature range, and a second number of transmits for a day in a second temperature range, setting accumulation rates based on time of day/season/forecast, and so on).

In some embodiments rules are defined to allow exceptions to a budgeting system, for example exceptions such as observations indicating “battery close to failure” or “sensor disconnected”, and additionally for the likes of reconnects and physical button presses. In some embodiments a maximum transmit credit accumulation value is set, so that if the transmit buffer is approaching capacity, extra accumulated values are allocated over a given timeframe.

Specific transmit triggers are in some embodiments enabled, modified or disabled on external influence, such as: time of day; known user vacation; user location; power usage; power usage patterns; location of other people; grid health; weather; battery level; and so on. For example, a given user might not want to trigger transmits at all while people are sleeping. Alternately, a user might only want to transmit on particular events of concern.

In some embodiments, when the battery voltage reduces below a predefined threshold, transmitting is slowed down significantly or switched off to preserve battery (for example such that consumption data relevant to billing is not lost, even if it is transmitted with very low regularity).

Monitoring Device with Common Connection Port for Multiple Sensors

Some embodiments provide a monitoring device configured to monitor a physical meter, the device including: (i) a microprocessor configured to execute software instructions; (ii) a communications module configured to communicate with a remote server device; and (iii) an input port configured to enable selective connection to any of a plurality of compatible sensor devices, wherein one or more of the sensor devices are configured for monitoring physical behaviour of a meter component.

In some embodiments the selective connection includes wired connection, for example using a 3.5 mm headphone jack (as discussed in more detail further below). However, various other forms of wired or wireless connection may be used.

Preferably, one or more of the sensor devices are configured for externally monitoring physical behaviour of a meter component. That is, rather than monitoring internal operations of a meter (for example internal voltage and/or current measurements), sensors are configured to externally monitor the activity/behaviour of a meter component. This in many cases allows the sensor to be mounted externally of a meter without a need for special tools. Various examples of such sensors are provided below. In some embodiments the input port is additionally configured to connect to a sensor that enables internal monitoring of the meter, for example where a meter is inherently configured to provide internal data to an external sensor.

In overview, sensors adapted to externally monitor meter components may include:
A sensor configured to monitor a spinning disc type meter component. For example, an infrared proximity sensor may be used.
A sensor configured to monitor a flashing LED type meter component. For example, a light sensor may be used.
A sensor configured to monitor a contact switch type meter component.
A current meter (in some embodiments a current meter is attached to mains power, such as mains power for a house, thereby to obtain more detailed information regarding power consumption, thereby to increase accuracy and/or effectiveness in appliance identification/detection).
A current transformer may be coupled to a wire, thereby to serve as a sensor that monitors current variations in that wire.

As described in more detail below, a device such as device 100 may include a single input port that can receive any one of these. Preferably, the device is configured to automatically detect a sensor type of a sensor coupled to the input port, and execute a predefined configuration associated with that sensor type. This allows the device to self-configure based on the form of sensor attached.

In some cases a single monitoring device includes a plurality of like input ports, allowing for the connection of multiple sensors. For example, this may allow for monitoring of multiple meters, for example meters for multiple utilities (for example electricity, water and gas). In some cases, one of the ports is used to monitor an electrical output device, for example where solar panels are installed which output power back into an electrical grid.

Some known devices are configured to operate with many cables and many different connectors, for sending many different types of information. Connectors can be expensive and having multiple connectors only adds to the cost as well as increasing the size of the product. Increasing the number of connections in the cable and the connector only adds costs. Embodiments described herein solve this problem by creating a connector configuration with interoperable form factor, to allow for auto-detection of different sensors plugged into the same port. One port can detect and switch multiple sensors to the proper electronic reducing part count, cost and board complexity.

### Exemplary Sensor Interfaces

Whilst embodiments make use of a range of input ports and coupling techniques, one approach is to use a four-conductor connector, such as a 3.5 mm headphone jack (or other forms of 3.5 mm TRRS, TRS and TS connectors). This a particularly suitable approach so since it allows flexibility for customisation based on a range of devices, allows any device to be plugged into any port and allows to use a off-the-shelf familiar mass produced plugs (which are familiar to ordinary consumers). Device 100 may include a single port, or multiple ports (hence allowing connection of multiple sensor devices).

A preferred interface has 4-pins, with a master side and a slave side (noting that in some embodiments a multi-master arrangement is used). The master side preferably uses a female jack and is located on the CPU/controller side, and the slave side is preferably located on the sensor side. Substantially any four pin connectors may be used, but because of price and availability, it is advantageous to use 3.5 mm TRRS, TRS, and TS connectors.

A standardized sensor interface according to one embodiment is configured to enable detection and interaction with one or more of these generic sensor interfaces:
A generic 4 line sensor (Generic 4), which has a power pin 1, serial data (SDA) pin 2, serial clock (SCK) pin 3, and ground (GND) pin 4. This is optionally powered by a I2C/TWI interface.
A generic 4 line sensor with interrupt. This is the same as the generic 4 line above, but uses a predefined level of current on the power pin to generate an interrupt.
A generic 3 line (Generic 3), which has an analogue signal pin 1 and a float pin 2, with pin 3 and pin 4 being connected to ground.
A generic 3 line alternate (ALT), with an analogue signal pin 1, float pin using pin 3, with pin 2 and pin 4 being connected to ground. In some embodiments set one line is set as an interrupt, however, in a preferred embodiment of the configuration, a generic 3 pin sensor is used for intake of an analogue signal.
A generic 3 line with interrupt: power signal 1, analogue signal 2, with pin 3 and pin 4 to GND.
A generic 3 line with interrupt: power signal 1, float pin 2, with pin 3 and pin 4 to GND.
A generic 3 line ALT with interrupt: power signal 1, float pin 3, with pin 2 and pin 4 to GND.
A generic 2 line (Generic 2) with interrupt: powered signal on one pin, pin 2 (3 and 4) to ground.

Another option is to provide a generic 2 line with only power and ground. This is optionally used in combination with another port to provide power where there is only sensing.

As described above, pin numbers do not dictate pin order, and a simply used for labelling. Additionally, it should be noted that connectors may also have a trigger for sensing whether something is plugged in (or not). Many known connector components have this feature built in.

Additional sensors are used in further embodiments. For example, known 1-wire communication protocols are optionally used in place of standard I2C/TWI protocols, this enabling reduction in pin count (and/or creation of new sensor types_.

Given that an I2C/TWI interface requires any data/clock lines be pulled high through a resistor, detection of the different sensor types is achieved by observing pins 2 and 3. Pins that are floating will read a high level, where pins that are grounded will read low level. If both are tied high, such is the case with a generic 4-pin line, further detection can be made by defining a unique address or unique set of addresses on the I2C/TWI bus for a given type of sensor. A given sensor optionally is assigned multiple addresses, provided the combinations of addresses are unique (or the address itself is unique to that type of sensor).

In some embodiments, the power pin is used to send data by monitoring current draw, and then drawing more power to send information, such as an interrupt. This power can be used, for example, to flash a light (instead of simply dissipating heat) or rapidly charge a capacitor and using that to power the device. In some embodiments, functionality is also achieved by drawing lesser power than normal. For example, one exemplary sensor includes a capacitor to maintain power on the sensor while it switched off its own supply for a short period of time. The interface (at the beacon device side) is configured to identify the change in current (for example using a current sensor and comparator) and perform an associated functionally in response (such as driving an interrupt).

In some embodiments, variation of current draw is implemented such that a plurality of current draw values (or ranges) are associated with respective meanings (for example a series of function dependent interrupts). In this regard, one approach is to determine a constant draw for normal operation, associate stopping all current with “situation A”, and associate a high current draw with “situation B”. This is advantageous in a situation with two IC's that both had the ability to send an interrupt to the processor, or one IC with two different interrupt conditions. If there is a chance of both interrupts being triggered at the same time at the same time, levels are preferably defined based on the combination of the two (thereby to identify simultaneous interrupts as a specific event) or the interrupts are in some embodiments ordered in accordance with a defined protocol.

It will be appreciated that not all sensors draw the same “normal” current, and hence there are challenged associated with assigning the same current levels to identify interrupt events across a range of sensors. One approach is to use a fixed threshold, for a solution where a sensor draws a small amount of current for normal usage, and a lot for the interrupt, and/or one where a sensor regularly draws lot of current but cuts power for an interrupt. For instance the interrupt simply changes from high going to low going. However, in an embodiment where the device is configured to operate with a plurality of sensors that have different normal current draw levels, and there is no clear overlap where a single threshold is able to be defined, then the thresholds are preferably set dynamically. That is, the device performs a method including: (i) identifying a connected sensor; and (ii) defining interrupt thresholds based on rules associated with the identified connected sensor.

In some embodiments, the processing unit is configured to accept designed sensors with a generic 4-line with interrupt, generic 3-line and generic 2-line with interrupt.

Generic 4-line sensors are in some cases configured as I2C/TWI sensors. These sensors sink milliamps for the order of milliseconds to trigger an interrupt. In some cases, device uses that (otherwise wasted) power for triggering the interrupts flashes an LED to provide a visual indication of what is effectively the sensor detection rate.

Generic 3-line sensors are in some embodiments configured as Current Transformers (CTs). The device optionally CTs which are specific to the system. CTs are made with differing resistance, and identification is achieved by applying power to an analogue pin and measuring the current flowing through the CT. It should be appreciated that attention should be paid to wattage limitations of the desired CTs to limit the current, to reduce likelihood of burning out the CT. A resistor switched in series is optionally provided to assist in limiting the current.

In some embodiments, other 3-line sensors can be added and differentiated through monitoring their respective current consumption. After the identification is made, device hardware automatically adjusts its operation based on the identified sensor and appropriate electronics. For some CTs, this includes analogue filtering and conversion to a digital signal.

Generic 2-line sensors are preferably configured to detect an open and closed switch. Interrupt is pulled low when the switch is connected. In order to conserve power, once an interrupt is detected, then power is turned off for a short interval, typically being the interval it takes for the switch to turn back on given the disc speed (where the sensor monitors a spinning disc type meter component). In the case that an interrupt is detected as soon as power is supplied, the power is turned off again, and the waiting period is applied again. In the unlikely event that all consumption stopped just as the meter was switching the switch (after several intervals have not shown a released switch), this indicates that the switch is stuck closed until consumption resumes, and an interval can be set that is equal to or less than the maximum time between the switch opening and closing given maximum consumption (it is almost one complete measurement cycle, or better described as one complete measurement cycle minus the time the switch is closed). Maximum consumption conservatively is in some embodiments the limit of the meter, or if more is known about the circuit, maximum consumption is in some embodiments calculated from the devices on the circuit.

In another embodiment, which is advantageous from a cost perspective, the processing unit is configured to accept only generic 4-line sensors and generic 2-line sensors. In this embodiment, CTs are preferably modified into Generic 4-line sensors by offloading some of the circuitry on to the CT hardware and converting the signal in the unit. However, the standardized sensor interface remains the same.

### Exemplary Sensors

As noted above, there are many types of utility meters and, while many of them are similar, there are distinct categories and many ways to measure the meters. For example, there are disc meters, digital meters with led indicators, digital meters with serial readouts, smart meters, meters that have a switch that closes every consumption period, current transformers, off the shelf meters, meters built into appliances, etc. Using a generic interface, as disclosed above, enables a variety of compatible sensors to be plugged into any free port of a beacon device, such that common beacon device hardware is able to operate in conjunction with a wide range of utility meters. A variety of exemplary sensors are described below.

A circuit for triggering a specific current pulse of specific current is preferably integrated into sensors described below. This can be created by way of a monostable pulse circuit, or with other dedicated electronics (such as a programmable IC or raw components). The input to trigger is preferably an interrupt line that is active for a variable amount of time. There can be multiple triggers tied of different currents, for different lengths of time to relay more information. In some embodiments, the pulses are used for time stamping.

A first example is a sensor configured to monitor a spinning disc type meter component. This takes the form of a disc edge sensor, being an IR proximity/reflectance sensor IC, using a generic 4-line with interrupt. This type of sensor uses a standard infrared proximity sensor, which also detects reflectance in the IR spectrum at a fixed distance. It will be appreciated by those skilled in the art that many such sensors are readily available, both as a single IC or as series of IC's. In selecting an appropriate sensor, it is relevant to ensure that the detection rate is at least fast enough to detect a disc marker when the disc of the meter is spinning at its fastest rate. Though these sensors are conventionally referred to as IR proximity sensors, in most standard off the shelf varieties, they are proximity sensors for a given target surface reflectance, and can hence also be used as a target surface reflectance sensor given a certain fixed proximity. The more sophisticated IC's include built-in ambient light rejection of many varieties. Unless operating in fixed lighting environments, built-in ambient light rejection makes implementation much simpler.

Other embodiments make use of a non-infrared sensor: the light emitter/receiver can be of substantially any wavelength which is reflected and absorbed by most standard meters disc (which typically include black marks on an otherwise reflective edge).

The sensor is configured is configured to be mounted such that the light is directed at the disc from above from the edge (or even at an angle).

A proximity monitoring function of the sensor is in some embodiments occasionally read to identify whether the sensor has moved away from the meter (or meter component). It should be appreciated that sensor inaccuracy errors may occur in the case that the range the proximity sensor changes outside of the noise range of the system, or at a rate that is inconsistent with the edge of the disc speeding up or slowing down over worst case energy use (which occurs, for example, when a threshold number of electrical devices are turned on or off at once, rapidly).

The sensor is in some embodiments configured with a set threshold, thereby to generate an interrupt when the black mark or a sensed spinning disc meter component passes. However, in some cases finer resolution data is taken. Since the edge of the disc is generally not exactly the same color (it has defects that vary the reflectance), some embodiments configure the sensor thereby to take readings by recording the reflectance pattern of the edge of the disc (which is cyclical), and identifying a pattern that re-emerges each cycle (for example by setting a range of rolling interrupts that mimic the curve at some resolution). One way to achieve this is to constantly change the threshold to anticipate another point in the cycle.

In some embodiments, a variant of the sensor described above includes multiple sensing components (and optionally optics) to identify multiple points of reference on the disc. For example, this optionally includes enlarging the edge of the disc, or having a sensor on the top, bottom and edge to obtain multiple feeds, or multiple points along the front of the disc. This could include “zooming” in to the edge of the DISC to obtain multiple unique reflectance traces from the edge of disc.

Another example is a sensor configured to observe an LED meter component. For example, a preferred LED sensor includes an ambient light sensor IC, using a generic 4-line with interrupt. This sensor is in effect a light sensor, which is optionally an off the shelf IC or built up from components. Many off the shelf sensors have extremely low power consumption, which is preferable. A light detection threshold is set to define a flashing light from a non-flashing light. This is preferably calibrated for the environment. The threshold can be static or shift with a shifting environment. The sensor components are selected such that the sensor is enough to catch a light pulse. For example, the fastest pulses for known meters are currently are around 5 ms. Accordingly, the sensor needs to sample at least 5 ms, but preferably faster than that (1 ms is preferred so that multiple readings will detect the pulse).

The light detection threshold is preferably adjustable. For example, as the background ambient light shifts (for example over the course of a day, or as nearby lights are activated), the threshold level shifts to account.

Another method of noise detection includes identifying the pulse profile of a flash, which is fixed pulse length on the order of milliseconds, (less commonly, a 50% duty cycle flash) of a brightness that will lie in some range. This is in some embodiments predicted based on knowledge of the type of meter fed present, or detected in a controlled lighting condition of startup. A controlled lighting situation (for example one which includes observing the ambient light with another sensor located nearby but faced in another direction) may involve shielding the meter from light by throwing a cloth over it for a minute or by asking the installer to confirm that the light isn't changing rapidly or something to that effect. By reading off many values one can look for brightness shifts by examining the slope.

Another example provides a sensor similar to that above, but where sensitivity of detection is peaked where the color of relevant LED matches the detector. For nearly every modern electricity meter, this falls within the red spectrum.

Another example provides a sensor similar to that above, but in the context of series of sensors or a single sensor with a series of changeable filters, which each filter the color ranges specifically, so that the sensor can be manually configured during installation with a particular to a filter or series of filters that best match the color of the LED. This is in some embodiments tested for, preferably during a controlled light period.

Another example provides a sensor similar to that above, but with multiple color channels. These include color channels configured to detect desired detection wavelengths, and color channels that exclude the desired detection wavelengths. This allow for multiple points of reference when detecting flashes. The color channels are read and relative thresholds used to determine detection. For example, if you have a red, green and blue channel and red is to be detected, detection can be triggered at having a difference between the red detection, and between the other channels (hence assisting in excluding ambient light effects, which would be observed across all channels). Detection could also be determined on known light profiles, so if red went up a lot and green a little, and blue not at all, that is in some embodiments used to help determine detection. If red, green, and blue all increased proportionally, to a known or assumed light profile, such as sunlight or fluorescent light, then it is assumed the light is from another source so no trigger is needed. This is in some embodiments used in combination with the above method of watching for how long the light is on as well. This would be very good for noise immunity.

Another example provides a sensor similar to that above, but with a proximity detector to detect when the device is removed from the meter surface. If the proximity reading changes significantly, it can be assumed that the sensor has moved and needs to be setup again.

Another example provides a sensor similar to that above, but with a meter facing surface absorbs a large proportion of the color of light to which the sensor is sensitive. This reduces the amount of ambient light that can enter the detector.

Some embodiments make use of a CIE color detection threshold used to determine color, thereby to assist in distinguishing between a meter LED and ambient light. For example. One approach is to auto-calibrate a threshold value by looking only at shifts in color. Furthermore, when determining whether a light reading (for example a max/min threshold value) is indeed a value representative of power consumption (and not ambient light), a process is performed to confirm a color for light associated with the value. In this regard, after a threshold min/max value is determined for sensed light data, a rule is implemented to compare color with subsequent events to distinguish LED activity from ambient light activity based on color. This is optionally performed each time a threshold is read, or sporadically (for example periodically, or every nth threshold reading). This prevents a threshold re-setting based on changing ambient light levels being mistaken for a meter LED flash.

In some cases, meters have different colored lights representing different attributers (for example red for buy and green for sell). By using the above, when a threshold value is identified, it can be determined based on color to which attribute it applies.

In combination with the sensor above (narrow band LED sensors), a preferred configuration makes use of an adhesive material or spray on material, that specifically absorbs the sensor's sensitive wavelengths of light, is placed around the sensor or covering part of or the entirety of the transparent region of the meter. This effectively lowers the noise floor for that narrow wavelength of interest, while keeping majority of the visible light passing through, thus not significantly obstructing view of the parts of the meter.

Another example is a dual-use sensor, which provides an ambient/IR proximity sensor component, using a generic 4-line with interrupt. This includes a sensor component which contains both an ambient light sensor plus an IR proximity sensor, enabling a common sensor to operate for both a LED meter and disc edge sensor meter. That is, a common component is provided for customers with either LED type meters and spinning disc meters. Those skilled in the art will appreciate that there are various integrated circuits that are manufactured with both types of sense ability built in. One example is the MAX44005 from Maxim Integrated.

Dual-use sensors preferably have extended functionalities. For example, when the sensor is attached to a digital meter to sense an LED, the ambient light sense ability is used for the purpose of LED detection, and the proximity sense is utilized to monitor for tamper detection/device malfunction (for example to make sure the sensor is not removed from the meter).

It should be appreciated that any of the various aspects of disc edge sensor and the LED sensor described further above are also in some cases implemented in a dual-use sensor. Also, when attached to a disc edge meter component, the IR proximity sensor is able to double as a reflectance sensor and provide edge detection.

A further example is an edge movement sensor, using a generic 4-line with interrupt. Very high resolution sensing is in some embodiments accomplished by using a sensor that detects motion, for example by using a camera and signal analysis, or using a laser mouse type sensor component, thereby to monitor the edge of the disc. A generic laser mouse sensor is in some embodiments used, modified however such that the optics are adapted to focus the edge of the disc on the sensor.

In some embodiments, where an external device is able to supply its own power, a sensor could be powered by the external device. If it could supply a lot of power, this could power the beacon device as well, perhaps with an additional option to plug the beacon into the power of the connection.

### Buffer Management

Some embodiments provide a method for operating a device that is configured to monitor a physical meter, wherein the device includes a communications module configured to communicate data indicative of meter activity to a remote server device, the method including: based on input from a sensor device, recording periodic data points in a buffer; transmitting the data points to a remote server based on a set of transmission rules, wherein the buffer is cleared following the transmission; and applying a buffer management protocol, thereby to compress the data points in the buffer in response to a set of buffer management rules.

A key aspect to buffer management is that each data point represents power consumption, and the buffer management protocol is configured such that total power consumption data is maintained in spite of compression of two or more individual data points. That is, whilst data resolution might be reduced for certain time periods following compression, the total amount of power consumed remains accurate. Accordingly, various method implement a step of applying compression to a set of data points that each reflect a respective power consumption value, thereby to define a reduced set of data points (which may be a single data point), with the reduced set reflecting the same overall total power consumption represented by the respective power consumption value of the original set.

A preferred approach is to apply a compression algorithm, such that two or more successive data points are averaged (or summed) thereby to provide a single buffer value. Similarly, repeated values may be combined. For an exemplary sensor, a data format is defined based upon: start time for the measurement (s), end time for the measurement (E), value for the measurement (V). So to compress . . . S1, E1, V1 and S2, E2, V2, the result is S1, E2, (V1+V2). For others types of sensors a weighted average is calculated based on the value and the time.

It will be appreciated that each point represents power consumption, and a point in time. That is, the data comprises an electrical element (such as current or energy or power) and a time interval where that reading is valid. Data resolution representing precisely when particular events occurred can be lost through data compression, however the total amount of energy consumption over a compressed period remains the same over the larger interval.

Importantly, the approach is to compress time information (i.e. when a pulse happened) while not compressing the sum of pulses that happened. In this regard, some embodiments provide a memory compression approach which sacrifices time resolution, whilst retaining energy resolution. Practically speaking, a power bill at the end of a month will be the same no matter how much one compresses data. However, the ability to detect devices, for example by disaggregating a signal thereby to identify activation or deactivation of particular electrical appliances, is compromised as a result of compression. Accordingly, as noted above, there may be different protocols for handling transmit triggers for data relevant to overall consumption, as opposed to transmit triggers caused by the activation or deactivation of electrical appliances.

In some embodiments, points are selectively either averaged or summed, dependent on the data represented by the points. For example, energy is summed, whereas power/current requires a weighted average.

A progressive memory compression scheme which keeps the most recent data uncompressed and compressed older data may be used. That is, recent data is used for appliance detection, and older data is used for bill matching. So if needed, such an approach is implemented thereby to reduce the time resolution of older data, while maintaining the energy resolution.

The buffer management protocol is, in some cases, configured such that a set of relatively older data points are compressed to a lower resolution as compared with a set of relatively newer data points. This provides higher resolution for more recent data, which may be relevant in terms of defining notifications and suggestions for users. Relatively older data is less relevant in that regard.

Some embodiments make use of a memory compression scheme wherein memory is filled by averaging the last point filling a given point with the averaged value, keeping the time interval. The formula for the new value is, in some cases: average+(new value average)/(N+1) where N is the number of items in the old average. This lowers the resolution of the last point without loss of total energy.

Some embodiments make use of a memory compression scheme whereby the resolution reduction is spread evenly among all available data. Given memory spaces are even (odd values need an adjustment). Once memory is full of single values, value n is averaged with n+1 and pushed to the top. Spot (n/2+1) onwards is then filled with values n+1 and n+2, etc. . . . till 2n1, and 2n in spot n. The process can then repeat with averaging 4 values, and so on etc. This can be compressed in other multiples, however it will be appreciated that the equations will be slightly different.

Some embodiments provide a compression scheme where a first part of the memory stores the most recent data in an uncompressed form, and a second part of the memory uses the compression scheme above. This includes moving the uncompressed data into the compressed region each time the first part of the memory fills up. The uncompressed data is important for real-time alerts, and the compressed data remains appropriate for overall consumption monitoring.

Some embodiments provide a compression scheme which combines repeated values automatically. In some cases, if successive values are within a threshold proximity, an automated step is performed to compress and sum the adjustments.

Some embodiments provide a scheme where compressed data is marked as lossless or lossy, so they can be treated differently by the server (i.e. the server treats lossy data different to lossless data). This is in some embodiments a time or datum number where the switch occurs.

In some embodiments, highly compressed information that is of relevance to billing (such as 15 minute aggregate data) is held in memory, in some embodiments via an off-board memory unit. Such information is not updated often, allowing for longer term storage. This assists in managing complications associated with lengthy Internet outages and the like, or deactivation of a WiFi router (for example when a home owner is on vacation). In some embodiments, upon detecting that there is no WiFi and/or Internet connection, an automated process is triggered to compress increasing intervals thereby to preserve crucial overall resource consumption data for when connectivity returns.

### Device/Sensor Installation and Configuration

Monitoring devices, as considered herein, require a degree of installation and configuration. In particular, sensors need to be positioned appropriately to read relevant meter components. Sensors described herein are preferably configured to be installed with limited technical skill, but a degree of precision may be required (for example in the context of aligning an IR sensor with a spinning DISC type meter component) depending on specific hardware design. Various approaches for assisting with such challenges are described below.

In some embodiments, installation of the device in effect commences at the time of purchase. For example, if ordered online, the user is preferably e prompted through email (or a website, social media, or the like) to commence entering information about their device and its installation environment. This may include any one or more of: entering details form older resource consumption invoices manually; entering a WiFi password and SISD for a local network to which the device will connect; inputting details of types of appliances in the house; entering details of a resource billing plan that is in place; inputting a location of the house (or other install location); inputting a type of meter (for example including a serial number and/or photo); checking WiFi strength at the location of the meter (which may prompt purchase of an extender or the like). In relation to a meter photo, a meter image taken a period of time before the beacon arrives enables the usage over those days can be calculated, thereby producing a baseline as soon as the device is setup (i.e. comparing usage in the days before and after device installation). It also allows time to retrieve information about that meter so more is known at the meter at time of setup, which can be used to assist an installing user.

If the device purchased through an entity with which the user has a previous relationship (such as an electric company), data may be extracted from a database associated that entity. For example, an electric company provides data relating to previous consumption and/or invoices. If through a telecom, it could configure the device to connect to the public private WiFi. If as part of package with a router, such as an Internet service, the device can be configured to connect to that router through its SISD and password so it works right out of the box. A special router-associated version is provided by some embodiments so that the two devices have a special link via WiFi or the like so that the device follows router configuration step. For the example of routers configured to have a public access point as well as the private one, the beacon can be programmed to match the public one so it always works. When the package arrives at the home it could be looking for the customer WiFi network and tell the user when the package arrived. If on a public or semi public network it could send an alert when the package was close to arriving at the house or give live updates about tracking.

### Server-Driven Device/Sensor Configuration

In some embodiments, a user is instructed/guided with respect to a device and sensor installation via a smartphone application (or series of web pages loaded via a browser application). In that regard, some embodiments provide a method for enabling configuration of a monitoring device that observes a physical meter component, the method including: receiving, from a mobile device, data indicative related to the configuration; providing a signal over a network thereby to cause the monitoring device to perform a function observable by the mobile device; and receiving, from the mobile device, data indicative of observation of the performed function.

The data received from the mobile device includes image data (still or video) containing a portion of the physical meter. This may be used to perform image-based analysis thereby to identify a meter type based on the image data (for example by comparison with image data for a plurality of known meters). Once a meter type is identified, specific instructions may be provided to the user. Identifying the meter type may also be useful in the context of extracting from the image data a meter reading (such as a numerical reading).

In some embodiments GPS location is used to determine a user's location, and based on that location limit the possible number of meters (based on meters known to be used in that area. This can aid in automatic detection of different types of meters, or, if manually selected, reduce the number or change the order of the meters shown.

The function performed by the monitoring device may include providing a visual or audible signal. For example, in one example a sensor includes an LED, and the server causes the monitoring device to provide a flash pattern via the LED. This pattern is recognised via image analysis by the mobile app (using a mobile device camera module), thereby to confirm that the correct sensor is being installed on the correct meter.

The method may then include instructing the mobile device to provide instructions thereby to guide a user with respect to mounting of a sensor device thereby to observe activity of the physical meter component. The method may include receiving, from the monitoring device, data derived from a sensor and, based on the data, determining whether the sensor is correctly positioned thereby to observe activity of the physical meter component. The method may then include providing, to the mobile device, an instruction to present a notification representing successful configuration of the monitoring device.

Given that there are many different forms of meter, the process may include using image capture by the smartphone device thereby to enable automated graphically-based identification of a particular meter device, and from that determining a set of instructions that are to be delivered to the user's smartphone device. Also, in some embodiments data obtained via the smartphone camera may be used to determine whether a meter sensor is set up correctly, and branch a logical process of instructions accordingly.

In a further example, a message is sent to the monitoring device, thereby to cause the device to provide stimuli for guiding the user (for example a flashing light adjacent a port into which the user is instructed to connect a sensor). The smartphone application may furthermore provide direct access to interactive chat, voice sessions, and the like. Preferably, images captured by the user through the application are made available to human support representatives.

In this regard, advantageous aspects of a support infrastructure that operates in conjunction with configuration by a user having a smartphone device include, in various embodiments:
Interactive feedback for the user that involves indicator aspects of device to be setup, such as lights and sounds (confirmation, or instruct, such as smartphone: press blue button, Beacon: blue button flashes).
Smartphone identification of meter device (and meter device components), as well as environmental factors (for example feedback from the smartphone camera, or accelerometer, GPS, or whatever else). Smartphone camera feedback indicates, for example, the meter type, or that the sensor was placed on the meter correctly.
Data taken from the beacon device (or the server) is used as feedback, (for example, smartphone camera indicates: black mark has passed; beacon indicates: sensor has not triggered; action: Beacon auto calibrates; if calibration fails: smartphone jumps to a point in troubleshooting related to that failure).
Documentation of the process of setup (tech support can know where in the process the person has stopped, how long they spent on each step, etc).
Implementation of a setup process that is not linear (different people may have different experiences).
Server smartphone feedback: GPS is used to identify a location and correlate that with a database of meter types in that area (or even to the age of the building), and use that to customize the interface (for example predict meters, change visuals or perhaps details of instruction specific to a meter in that location).
Direct connection extended connection to support representatives (for example tech support is provided with access to smartphone hardware, such as a camera, and an ability to control the Beacon device, for example to switch on lights).

It will be appreciated that only a selection of these are present in some embodiments.

In some embodiments each device ships with minimal firmware that only allows a connection to the relevant authorized servers, and general debug and/or setup functions. To fully use the device it must register with an authorized server, and download additional software instructions (i.e. code). This may coincide with a cross-checking of device data (for example a serial number) against sales/distribution data, thereby to determine whether a device is authorized for use. Furthermore, a device may in some embodiments be pre-locked to a user account; if the user ordered the device over the web it is pre-locked to the purchaser's user account. This is helpful in managing theft and the like. If bought in-store, when set up, it can be locked to a user using a board serial number or the like (as another approach for preventing functional use of stolen devices).

### Optical Sensor Alignment

Various sensors considered herein require precise alignment, for example with respect to the location of a spinning DISC type meter component.

In some embodiments a sensor unit includes multiple sensors offset from each other. This allows for testing of each sensor following installation, thereby to determine which is best aligned, and then configuring the monitoring device to use only that sensor. For example, multiple IR emitters may be pointed at spaced apart positions, along with one or more IR receivers to receive reflected IR signals. Another approach includes a light or laser which is aligned with the optical path of the sensor so the sensor can be visually aligned. Sensors such as these are in some embodiments mounted directly to the meter with an adhesive, preferably a strong and removable adhesive. Or it is in some embodiments mounted with a mounting bracket preferably a one axis bracket is optionally configured to rotate off the center of the axis of rotation (the sensor, is preferably round rotating on its axis), and align the parts. The maximum off center the mount could adjust for is +/the distance between the sensor and the axis of rotation. If stops were employed, the maximum would be: (the distance between the sensor and the axis of rotation)*tan(max rotation angle).

### Optical Sensor Mounting Brackets

One of the issues with mounting anything on a meter that many people read and use is that, no matter how careful one is about placement, there is a chance that someone, such as a service technician will need to see under the mounted device and will remove it from the meter. Also, if there is ever an issue with the sensor, such as a damaged cable, one may want to replace the sensor without having to go through a lengthy realignment procedure. Many of these issues can be solved by using mounting brackets.

One embodiment provides a mounting bracket that captures the sensor head so that the head is held in a fixed position, however allowing the sensor can be easily removed and reliably replaced. The mounting bracket is preferably formed of clear material to allow for an unobscured view of the meter. It is preferably mounted to the meter using an adhesive, preferably clear, removable and strong. To help with handling the bracket, the bracket may be built with adhesive wings, which can be folded down, once the bracket has been moved into the correct position. Clips, or bracket shape, hold the sensor in place. In some embodiments mounting aids such as 3M Dual Lock or Velcro are used to assist in attachment an alignment. It will be appreciated that a view of the meter is better with the sensor not installed, than with it installed.

In some embodiments, a sensor mounting bracket has alignment marks along one axis, for example, a single straight line (without obstructing the sensor view) so that one, can for example, align the bracket reliably with the disc of a disc sensor. There may be a second line, thread, fin or marking in the optical path to reduce parallax.

There is a chance, regardless of mounting hardware configuration, that mounting may still be inaccurate, for example because (for example) the meter is in a hard to reach place, the installer's eyesight isn't very good, or the installer does not completely understand the alignment procedure. One solution to this is to notch the mount, so that the sensor can slide in one direction perpendicular to the alignment marks. There will be an optimal detection range for the sensor so as long as one places the sensor within a certain range, the device can be calibrated. The adjustment notches should be a distance apart that is less than that optimal detection range on the axis of travel. By allow a short amount of fixed movement, the installer can follow a systematic procedure for aligning the sensor following installation of mounting brackets.

A two axis bracket may be similar to the one axis bracket but have two axes of alignment. A disc meter sensor would be more likely to use a one axis bracket where an LED meter sensor would more like use a two axis bracket.

A bracket for an LED meter which is configured to monitor sensor proximity to the meter (to detect fall off) requires a gap between the meter and the sensor. For disc meters, wherein a window of glass or plastic is provided, this is typically not required.

In some embodiments, optical sensor alignment is achieved by way of a lens which fits in a bracket around the module, thereby to assist magnify for visual alignment. The correct focal length is preferably selected using standard lens equations, and knowing the range in which a disc conventionally is located relative to the surface of a disc compartment window. Two lines, or doubled crosshairs, in the optical path are preferably provided to reduce parallax error. For example, one embodiment includes a lens with a line on the top and bottom surface, and those lines are aligned to indicate correct positioning. In some embodiments a cylindrical lens is used, thereby to magnify a disc's most important dimension. In some embodiments lens halves, or dual lenses, provide different strengths next to each other thereby to assist alignment by optically exaggerating parallax error.

In some embodiments, the lens is used for assisting in mounting, and also for meter component behaviour detection. For example, a lens is moulded into a base component, and is configured for alignment and also to enhance sensor observations.

### Disc Meter Calibration Method

Once a disc sensor is attached to a disc type meter in a proper position, a fixed default setting is unlikely to work on all meters across the board, and a calibration is preferably performed thereby to achieve proper function of the sensor. In some embodiments, during the calibration, IR sensor settings are varied such as effective sensor sensitivity and effective drive strength. The calibration also preferably involves identifying critical points which can be used for thresholding. Most IR sensors have an analogue equivalent for sensing distance and setting thresholds.

If the sensor cannot be read internally to the sensor IC, an external ADC could potentially be used. If no ADC is available, simply varying the threshold until an interrupt is triggered allows for probing this analogue channel. There generally will be some settings that can vary the strength of the signal. For example, the signal should lie well in between the low read value and the highest read value with the largest dynamic between black and silver. Since the black mark on the disc is usually a known small fraction of the wheel, one approach is to monitor the wheel for a period of time anticipated to comprise several rotations (either through user feedback, or simply estimating from how fast meters generally move or by asking the installer to turn on some appliances to increase the speed of the disc).

If the sensor ever goes out of range, the power settings are in some embodiments changed. The level could then be set appropriately by taking the minimum and the maximum, taking the average and shifting it a little, or by find the level where the ratio of the points above and below the level match the proportion of the disc that is black.

The setting for the emitter strength/sensor sensitivity can be experimentally set. The setting can be ordered, for example, lowest strength to highest strength or searched like a binary search tree—(setting middle, then asking is it too high or too low, then adjusting to the middle of the new range and repeating the process). The strongest and the weakest values can be taken first to give a high and low to the range. One method for finding this is to set a particular setting and take several readings. Whether the sensor is looking at the silver or the back can be irrelevant though knowing this information through user feedback could help better center the sensor. Additionally, instructing the user to turn on loads to speed up the DISC such as turning on the lights or turning on a space heater is in some embodiments useful as well. Once a reading is taken, this can be compared to the usable range (this may be set by the total range of the ADC or a narrower range set by known limits of the system.)

Another method, which is faster but less reliable, assuming the minimum disc speed is known, includes taking the maximum of several sets of readings, ignoring out the lowest (which should represent the black mark), and then assuming that those readings are the silver portion. Then setting the threshold a fixed amount below that (which would indicate the black mark). In experimental setups, there exists a fixed range which can be assumed to work for all values.

Once a threshold is found it can be checked by waiting a reasonable amount of time and making sure that the interrupts are observed in a reasonable fashion. For example, a double interrupt is observed, the energy consumption will regularly be recorded as double the actual value. This can be identified and accounted for based on principles concerning prediction of a reasonable amounts that the energy consumption will increase at one time. A reasonable amount for increase can be found based on appliances found in the typical home. Automatic appliances like water heaters, can turn on at any time, things like air conditioners and heaters are unlikely to be in used at the same time. The threshold can be increased or decreased dependent on the readings.

Once a threshold has been confirmed, it can be further tuned and confirmed by taking readings right after it crosses the threshold in both directions. The difference between those two sets of readings can set as the new threshold. This can then be confirmed again. This can go on indefinitely, happen periodically, or stop after initial calibration period to save power.

As noted, during installation, a human can recognize if a black mark has just passed. This can be fed back to the system via a smartphone (for example a touch screen tap each time the mark passes) thereby to let an algorithm know the approximate rate the mark is travelling, allowing for a wait time to detect multiple rotations be determined, or to examine an area for a black mark or to ignore and area to set up for a light mark.

Another embodiment may involve taking readings over a period of time and performing statistics on the measurements. This is particularly useful for discs which are being sampled faster by the sensor, or are moving slower or have more surface texture causing greater variation in the readings. Given that the disc is most of the time in the silver position, the mean over a sufficient period of time (preferably one or more rotation) will give the mean level of the silver and the standard deviation will give an indication of how much noise there is on the disc. The maximum and minimum can also be tracked. A threshold can be set by using these values.

One way of setting a threshold using these statistics includes setting the threshold as ½ (though this could vary from ¼ to ¾ depend on experimental results) between the minimum and a defined number of standard deviations (in some embodiments being 2, but in other embodiments between about 1.5 and 3) from the minimum (note this would be from a maximum in the case of LED auto calibration). If two 2 standard deviations from the mean is below (or within threshold proximity of) the minimum, then there is no good threshold and the calibration should be re-attempted.

The minimum is in some embodiments a filtered or processed minimum. For example, the minimum could equal the minimum of (i) the max of the last three readings; and (ii) the previous minimum.

The threshold for detecting the start of the mark could be different from the end of the mark. It would be common to add some hysteresis to the threshold on detecting both sides of the mark.

After a threshold is set, a test to make sure the threshold is properly set is preferably implemented. Power consumption tends to change in steps for single family homes so getting some number of consecutive marks (two or three) which are within some time tolerance (maybe 1%) is optionally determined to indicate proper attachment. If the user was unlucky enough to perform the configuration during a change in power consumption, then the process can repeat.

### LED Auto Calibration

Some embodiments provide a method for automatically getting a pulse. It is preferably done with confirmed controlled lighting such as fixed normal lights or with an opaque cloth thrown temporarily over the meter. The sensor constantly senses the light and when it sees a dramatic increase in light it takes note and waits for a rapid decrease (note that the raw signal may need some smoothing). This increase decrease cycle is the pulse width. If this is about 50% of the time it is a 50% duty cycle meter. If not, it is assumed the pulse length is assumed fixed. Average values for when the light readings are high, versus when they are low are found.

If the signal is noisy, taking the minimum of the values while high, and the maximum of values while low and setting the threshold anywhere in between will work. If ambient light is an issue as it will be on most meters. The threshold should be set closer to the higher value.

Another method of calibrating may include taking values for long enough that it is known that there likely multiple flashes included. And setting the threshold between the minimum and maximum value 50% is safe. If the noise of the signal is known or is characterized ahead of time the noise found in the field, one can place the threshold as the maximum value minus the maximum possible noise minus some safety threshold and confirm that is higher than the minimum plus the noise.

The LED auto-calibration in some embodiments mirrors the DISC auto calibration in terms of setting thresholds based on standard deviations, however it will be appreciated that it a maximum reading is required to identify the presence of LED light (whereas a disc black dot gives a minimum reading).

In the case of a 50/50 duty cycle LED (that is, one that is on then off), a configuration algorithm is run based on the difference between successive points. LEDs turn on and off very fast. This algorithm processes the difference between two successive points. When the difference is large, there is an “edge” (i.e. on/off event). By looking at the values before and after the edge, a threshold can be found in between those points.

The success of an LED threshold can be determined by looking at the CIE color of the LED after a detect event, when the LED is on. If it is the expected color, usually red, then the detection can be seen as a success. Another test would be to see if the length of the pulse is typical to the meter. Additionally another test could determine if two or more points, one after each other are the same time apart (note that again this is prone to false negatives).

### Exemplary Current Transformers

One example of a current transformer is a “simple Current” Transformer, using a generic 3-line interface. If the transmitting unit has a hardware implementation, a simple current transformer can be used. This is simply the current transformer wired into the plug. It is read by the transmitting unit and it is inexpensive to purchase. However it is both expensive on the transmitting unit and on the power side.

Another example of a current transformer is a “smart” Current Transformer, using a generic 4-line with optional interrupt. A smart current transformer includes built-in circuitry (built into the sensor or connecting cable) that is configured to obtain and compress sensed data, such that the data is provided to the beacon device in that compressed form. This reduces processing overheads at the beacon device. It also increases the quality of data, since the signal is processed near where it is collected. An interrupt is in some embodiments triggered when a compressed set of data is ready for offloading.

In current sensing applications, it is important to measure voltage and current with high accuracy, thereby to determine energy use. Additionally, in some situations, energy use is not the critical information (or not the only critical information). For example, a peak detect and averaging over a minute provides an adequate “fingerprint” to enable appliance detection. Appliance detection is also assisted by providing and enabling subsequent processing of additional information that describes the waveform (such as like the number of peaks, RMS versus maximum, and/or information about the shape of the waveform, a low resolution FFT).

### Exemplary Contact Switch Sensor

Some embodiments make use of a contact switch detector, for a meter that includes a contact switch (i.e. operation of the contact switch is representative of electricity consumption). A generic 2-line sensor arrangement with interrupt provides a convenient option. In particular, the sensor is configured to place voltage on the meter's line, and monitor for a current draw (which occurs when the contact switch closes). Current draw events are identified. The sensor is configured to deactivate for a period of time and re-activates. If there is still current draw it turns off again and check a short time later. When there is no current draw when turning back on, it stays on. The next current draw is another pulse.

Another approach is to use a sensor as described above, but with the addition of a resistor in parallel. This provides for a small amount of current draw when there is no contact (i.e. when the switch is open) to indicate an operational connection to the sensor.

### Exemplary Generic 4-Line Sensor Adaptors

Generic 4-line sensor adaptors are used in some embodiments. These are made by packaging integrated circuits configured for protocol translation into the standard form factor. An example of this is a UART to I2C/TWI conversion integrated circuit. As an alternate, in some embodiments a microprocessor is used to perform such a functionality, and an advantage of a microprocessor is that it is configurable to filter out irrelevant information and only wake the main processor (of the beacon device) from a sleep mode occasionally, as required. These units, in some embodiments, are read constantly, or enable an interrupt in low power mode.

In some embodiments this form of sensor adaptor is used in conjunction with an electrical weather station arrangement.

### Standard Protocol Sensors

Some embodiments provide standard [protocol sensors. These are sensors that send data to the beacon device (or directly into the networked system). Examples include WiFi sensors, Bluetooth sensors, and Zigbee sensors. For example, a manufacturer may choose to add these protocols to sensor units, or add a sensor adaptor that collects this data. These send the relevant collected information to the server. This is useful where there is a desire to avoid expending energy or technological expense to communicate directly between servers and sensor devices.

Smart appliances could possibly be monitored via a standard sensor interface or more likely they will have their own protocol communicating with their own servers and it will be up to the server to receive or poll for that smart appliance information and incorporate it into its data analysis.

### Virtual Sensors

A virtual sensor is a stream of data that is brought into the system in real-time, that is processed in a way that has direct relevance to the system. This is best maintained in the server. For example, if an installed solar setup has an API, then data is pulled by the server that data directly from the source via that API. Another example includes filtering live solar radiation, in combination with a specific house location, in combination with the time of day (position of the sun in the sky), which is achieved by filtering in real time and recording the expected solar energy falling on particular solar panels. This is optionally enhanced by analysis that predicts where wind is blowing any cloud cover, and what the solar energy is expected to be at a given location. This data is very specific to an individual stream and may only be important in real-time to a specific person in a specific location. Accordingly, that stream of data may be individually fed to the system in real-time so that predictions can be made. Another example includes taking two streams of sensor data and combining them to make a real-time stream of data (for example taking the sum of the energy bought and sold in the context of an in-home solar collection system).

### Setup and Identifying Reliable/Unreliable Data (Tamper Resistance)

One embodiment provides a method for identifying reliable (or unreliable) data for a sensor by way of a distance/proximity sensor component in a sensor. By setting a distance threshold after the sensor has been installed, a distance/proximity sensor component is configured to identify when the sensor is moved. Once installed, the proximity value should never change (beyond noise tolerances). Before installation, the range should be have acceptable limits dependent on the readings typical of desired acceptable meter types. For electricity meters this should range from 0 to a couple of centimeters. If the device is moved, the data is marked as unreliable until sensor is reinstalled. An alert is preferably raised to inform a user that the sensor requires re-installation.

One embodiment provides a method for identifying reliable (or unreliable) data for a LED sensor, utilizing involving brightness/darkness tracking. The flash of the LED will have distinctive characteristics. For example, it will have a particular brightness curve over a particular period time. This time period may be fixed, or may relate to the rate of power consumption. The flash will generally be characterized by being above a certain brightness level for a particular period of time, given a fixed sensor position. These distinctive characteristics are observed and recorded, thereby to validate whether a given observed event is indeed an LED flash. Additionally, other sensors components provided via a LED sensor could be used. For example, if there is a proximity sensor, it is optionally used to set a baseline after the LED is calibrated. This is used to detect if the meter is still in close proximity or not.

One embodiment provides a method for identifying reliable date for an LED sensor by way of a movement sensor such as an accelerometer. Since a meter should never move (except perhaps in an earth quake which can be externally verified), unexpected movement identifies unreliable data (for example indicating that the sensor has been removed, or otherwise moved away from its installation position).

One embodiment provides a method for identifying reliable/unreliable data for a disc edge detect sensor based on constant monitoring of a distance/proximity sensor. Once the sensor is installed and configured, a distance/proximity reading from a distance/proximity sensor component on the sensor shouldn't vary beyond noise levels. An initial approximation should be in a range consistent for the desired detectable meters for example, a range from near zero (for example 3 mm) on a silver colored disc, to 50 mmm may work well for standard electrical meters (for example standard meters in a given jurisdiction). Once the sensor is setup and calibrated, the range of values is recorded. This range should never change (beyond noise tolerances and the like). If the sensor reads outside that range (plus some small safety margin for good measure) then the sensor has likely been moved and the data is be marked as unreliable.

One embodiment provides a method for identifying reliable data for a disc edge detect sensor based on meter assumptions and/or meter database of the distance sensor. This optionally includes a method that stores thresholding information from all users and is sorted by meter models. When setting up a new user's meter an initial approximation for the thresholds are made based on the new user's particular meter averaged from the database of all the meters of that type in the system.

One embodiment provides a method for flashing a light based on changing a configuration within a sensor to trigger an intentional interrupt. It is useful to have a flashing light on these sensors, but in some embodiments there is no direct way to control this light. Accordingly, one approach is to set internal interrupt thresholds above and below the thresholds to generate an interrupt and flash the light indirectly.

One embodiment provides a method for aligning energy meter data to a point in time through the use of an internet connected camera device. From the internet connected camera device, most commonly a smartphone or tablet, an app can be run which allows the use of the camera. The camera can then take a picture, series of pictures or video of the meter with monitoring device attached, and provide that to a server. The server then confirms that the beacon device is setup and running at that time. The server can then process a photo and analyze relevant information from within image data (for instance using OCR, human transcription, or a combination of both) such as a current meter reading. If the device has a digital display that changes, a series of photos or video may need to be taken through all the display pages to get all the relevant information such as meter serial number or id, meter type, meter configuration. The image data provide point in time associated meter information, which is, by way of example, used to generate a start value for subsequent consumption analysis. One embodiment provides a method for reliable setup of alignment of energy data to a point in time through the use of an internet connected camera device. This provides some tamper resistance, or even proper meter identification to the process, by flashing the light on the sensor in a unique pattern while pointed at the meter, while using a mobile device camera to capture the pattern to confirm that it is that particular sensor connected to the meter. This method can also be used to identify which sensor is connected to the one being photographed (in the case of multiple sensors and multiple meters) as well as confirm that device is being properly installed.

One embodiment provides a method for identifying reliable data via multiple reading confirmations. As context, alignment techniques discussed further above and confirming accuracy within a data point is achieved periodically. Time above and below a detection threshold should either be a fixed amount (LED) or a percentage (LED alt, disc) of the total time, depending on meter type. If deviation from this observed, in an unexplainable way, the data might be corrupted at that point. For example, the sensor could have fallen off the meter, or excessive light pollution has caused the sensor to freeze up.

One embodiment provides a method for tamper detection using the internal accelerometer (or gyroscope or magnetometer or other orientation hardware) to make sure the picture is taken vertically. Because in many areas there are regulations about how meters need to be mounted, for example, vertically, right-side up in those areas (which may be everywhere) with the specific meters, in the above methods with an internet connected camera this method can be used if the internet connected camera has camera orientation hardware and software available. This can confirm the “up” direction in the photo to keep someone from, say, creating a fake meter and running it on the ground.

One embodiment provides a method for auto locating. During the setup with an internet connected mobile device having a camera, providing the server side system with a GPS location enables address information to be automatically (partially or wholly) added into the account by looking up the location using a mapping service. If the GPS coordinates are saved this can also be used as a theft deterrent, because if a device is stolen and a new owner tries to use it, their address will be captured. Also during the setup, the beacon device is preferably wirelessly connected to the mobile device. At this point, the beacon device is configured to deliver an internal Beacon ID and combine that with the GPS location to help identify possible users' accounts to set up.

One embodiment provides a method for identifying reliable data based on capacitive touch. In this embodiment, a capacitive touch sensor is integrated into any of the sensors, and configured such that when the sensor is touched, a notification is raised (to the beacon device and/or server) This is in some cases used to help install the device, for example, the device may want to ignore readings when the sensor is being place on the meter. Once the sensor is installed, the sensor should not be touched. If it is, the data is preferably marked as unreliable. In some cases this is used to trigger or increase reporting of the other reliable data methods in order to have multiple confirmations of reliable/unreliable data. It may also push or set a flag which can be acted on by the user such as “stop touching me.”

One embodiment provides a method for identifying reliable data based on an accelerometer (or gyroscope or tilt switch or other movement sensing hardware) in the sensor. This is configured to detect movement of the sensor such that, a flag is set to identify unreliable data until the device is reinstalled (or the flag otherwise cleared). In some embodiments the server is configured to reset flags in response to known movement-inducing events, such as earthquakes or the like.

One embodiment provides a method for identifying reliable/unreliable data, based on a face side switch. A switch on the meter side of the sensor is in some embodiments used to detect if the sensor is attached to a meter surface or not. If the switch is triggered (usually upon removal of the device), then the data is marked unreliable until reinstalled.

Some embodiments provide functionality for identifying an accidental trigger or missed trigger. For example, this may be performed at the beacon or at the server. For instance if there is an interval pattern of n,m,n−m, n where m<n or n,n+n,n, this is determined to indicate a double trigger or a missed trigger. Another method includes analysing frequency and duration differences; multiple large changes in a short amount of time are unlikely. It will be appreciated that further methods include adding or removing a point, and assessing whether the resulting data is more feasible.

On an accidental or missed trigger, data around those triggers is preferably analysed to check for regular occurrences. If it is, the data is in some cases adjusted and the sensor recalibrated or adjusted to avoid these issues on an ongoing basis. In an extreme example, the sensor may need to be moved and the user could be prompted to do so. Electric companies could be warned if too many points were marked as a potential issue to readjust the marks.

Time sync can cause an internal clock to jump. This may cause anomalies to occur in the data. In order to avoid this, clocks are preferably set to divide a change over many seconds, to allow auto adjustment. Max time stretch could occur over many seconds; each second adds 1.001 seconds for 1000 seconds. The server in some embodiments simply removes a point since it doesn't happen, often or combine with other points to smooth out the associated error.

A method for using reliable/unreliable data marking for using with the device. If data is marked as unreliable, the user may be notified to reinstall the device. Data may still be taken while even if the sensor has been marked as unreliable since the device may have been knocked off and put back on, however the data has to be confirmed as legitimate or not after the device has been reconfigured. If the data falls within the pattern of previous data, the system may continue to partially function. For example, it may not allow for validation of billing data (where there may be legal implications if reported incorrectly) however it may still attempt to do appliance detection (which may be of little consequence if incorrect).

### Device Security and Tamper Recovery

One embodiment provides a beacon device having a housing that incorporates a method of security. This includes providing a device housing/case which has an integral switch, such that when opening the case the switch is actuated and a signal is generated. For example, the switch is inherently pressed in the process of opening the case. If the switch is actuated, the device is configured to respond by delivering a message (preferably sent to the server) to identify tampering. This switch is in some cases also generally be used to send a message to the server (for example to manually cause a transmit event, which is optionally a particular form of transmit event associated with the manual trigger). Such a switch may also be used to define an event, like breaking a communications pathway or disconnect of a power source. Preferably, cables that connect sensors are held in place unless the case is opened, such that the switch is actuated in the case that a sensor is disconnected (as the case would need to be opened).

The switch preferably is configured such that if a mounting bracket is removed, the switch is actuated. For example, the switch extends to the surface of the meter (or other mounting surface), and is actuated upon removal from the meter (or other mounting surface).

Detection of battery removal is in some embodiments achieved by using mechanisms for attachment (such as screw holes) that are only accessible if the case is open

In addition to tampering in the form of case opening and/or removal from a mount, there is also tampering in the form of battery removal. Preferably, the device provides sufficient onboard power storage for at least one transmission upon battery removal or the like. This allows the transmission of at least one packet in case of battery removal. Sensor security is also a concern. As noted above, this may be achieved using a housing/case. In preferred embodiments, the device identifies an event when a sensor is disconnected, and a message is sent to the server immediately.

In some embodiments, preventing the stealing of sensors is facilitated by assigning each sensor a unique ID. The sensor reports this ID to the beacon following connection, and the beacon reports this to the server. In the case that a sensor is stolen, the user can report the sensor as being stolen. As a result, the server identifies the sensor as stolen, and is configured to identify if a sensor carrying the stolen sensor's serial number is connected elsewhere. For example, when a beacon is configured, the server checks whether the sensor serial number is valid or marked as stolen. The server can further cross-validate duplicate numbers with where and when those numbers were valid. The beacon could disallow use.

The server is in some embodiments configured to provide a GPS location of the stolen sensor (based on the location at which setup is occurring). When specifying the location, the server optionally instructs the beacon to which the stolen sensor is connected to identify the stolen sensor by flashing the light, holding it on, or flashing it in a specific pattern.

In some embodiments where the sensor includes a unique key and response pair, or other Cryptographic identifier.

In some embodiments the overall system is configured to prevent counterfeit sensors using systems similar to those used to prevent counterfeit ink cartridges.

Using the disconnect of a beacon or sensor to allow someone to know exactly when their device was tampered with or stolen which could allow quicker identification of thieves on security tapes or other time based recordings. If public networks are available and the battery still plugged in, the device can continue to report in so that its theft could be approximately tracked. (Wifi Networks would have names or IP addresses that would relate to a location). Available networks would relate to a location via triangulation.

One embodiment provides a method for data loss reduction through predicted battery low warning system. When batteries reach near end-of-life, the device is configured to send a message to the smartphone application asking the user to change the batteries in the device.

One embodiment provides a battery low warning system in which the device is configured to send a battery warning based on both battery level and location. For example, if the user enters an area near the unit it may give a warning. If the user enters a store where batteries are possibly sold it may choose to give a warning/reminder then.

One embodiment provides a low battery warning system which encourages battery replacement. This may include, displaying battery advertisements, suggesting that a user changes batteries, suggesting with an option to purchase batteries, sending as part of service, and so on. If the batteries are purchased through the app, the shipping tracking number are preferably be linked to the app so when the batteries arrived, the user could then be prompted to change the batteries. A user is in some embodiments prompted to enter battery type into the app via text or photograph so that battery lifetime estimates could be produced. Battery warnings are in some embodiments the user's mobile device if, for example, it got too cold or it was predicted to get too cold for the batteries.

In some embodiments a low battery detection event configures the device into a “keep alive” mode, which reduces power consumption by the device to a minimum state where there is no critical data loss. “Critical data” may depend on the use, but preferably includes 15 min interval data on a meter (for example a mains meter), thereby to retain overall consumption data for billing purposes. The beacon in some embodiments is configured to make decisions about what was “critical data”, which may be overridden by the server. But for example, temperature sensing could be slowed down if not turned off. Noncritical algorithms like dynamic threshold adjustments could be turned off. Transmitting could happen only on critical events. Non critical external sensors could be turned off while some were left on. Sampling quality could be reduced.

Some embodiments provide methods for retaining high quality energy data, including a combination of any of the above methods for data loss reduction and reliable data identification.

One embodiment provides a method for power failure identification. If the device is unable to communicate with the server, and/or if connected to an external power supply loses power to the external power, and/or if power consumption readings are no longer arriving (given a time period that is several times longer than is typical for that day), then the power can have assumed to have failed and the device is configured to raise an alert condition.

One embodiment provides a method for reporting in the case of a power failure. In event of power failure (for example as determined by a method such as described in the preceding paragraph), if the Beacon is WiFi based (or has another protocol which is based can communicate with a smartphone such as Bluetooth), and if a valid smartphone is in range, such as the smartphone which setup the unit, the beacon is configured to communicate to the smartphone and send its data out over the smartphone's cellular network. In some embodiments the beacon device additionally communicates to the server (via the smartphone's network connection) data pertaining to the fault, such as time estimated of fault. The user can then be notified and if the user has previously approved, the power company can be directly contacted, giving the power company a house level notification of exactly where the power has gone out. If the beacon device has access to an area network like 3G/4G, it can send the data directly. By observing where beacons devices still transmitting, and where the beacons devices are not transmitting, inferences are able to be made with respect to locations of power outages.

A further embodiment provides a method for detecting power surges. When a power surge occurs, often times there is a huge consumption of energy as appliances blow, fuses are burnt, and breakers are tripped. In some embodiments, the beacon device is configured to identify, via processing of meter data, a signature representative of a power surge and (if possible) alert the owner and/or other parties (for example in a manner similar to a power outage as discussed above).

### Overview of Server-Side Functionalities

Described below are various server side functionalities that are, according to some embodiments, provided by a device such as server 120. In overview, server 120 provides a bridge between data collected from meter monitoring devices, and user mobile devices (with each meter being associated with one or more user mobile devices). Each mobile device executes one of a set of specified mobile apps (for example iOS or Android software applications), preferably being proprietary apps (but in some cases a web browser may be used to access functionality provided via a web server as an alternative to downloading and installing an application).

The exemplary functionalities described below are preferably provided in conjunction with monitoring devices such as those described above, but are not necessarily limited to such situations.

### Behaviour Incentives

Some embodiments provide computer implemented method for encouraging resource consumption behaviour, based on the defining of a desired behaviour. The “desired behaviour” may be defined based on a wide range of factors, including the likes of environmental best practices, practical suggestions (for example based on weather predictions; such as encouraging washing of clothes based on a weather forecast). A particularly important subcategory is behaviours defined subject to resource provider input. For example, in the context of electricity, a provider may wish for users in a certain geographic location to reduce power consumption at a particular time thereby to achieve goals across a distribution grid (for example in the context of grid balancing, or in response to problematic peak loads).

The method includes providing a signal thereby to configure a plurality of client devices to provide, via respective instances of a software application, data indicative of a behavioural instruction associated with the desired behaviour. Each client device is associated with a user account, and wherein each user account is associated with a utility meter, allowing the instructions to be specifically directed based on substantially any attribute of the user. The behavioural instruction may include, for example, an instruction to reduce resource consumption (for example by a certain threshold amount, or by turning off specific appliances), in some cases by reference to a time period. It may also include suggestions on how to make those changes based on a user profile. For example, a person who has an air conditioner running may receive a suggestion to lower or turn off the air conditioning where as someone with an air conditioner which is off but a pool pump which is running maybe asked to turn off the pool pump. Someone who has does not have large loads may not be given an offer, where someone who has a potential for large loads which are off may be give an offer to maintain the current level.

The methods additionally include, for a given one of the user accounts, monitoring meter data thereby to determine whether performance conditions associated with the behavioural instruction have been satisfied. For example, in a simple case, this includes determining whether resource consumption has been reduced in compliance with the behavioural instruction. This is preferably linked to a feedback arrangement, whereby in the case that the performance conditions associated with the behavioural instruction have been satisfied, the client device associated with the relevant user account is configured to display data indicative of successful completion of the behavioural instruction (for example an instruction is associated with a “completed” or “on track” status in the user's app). The user status may also send alerts when one is in danger of not meeting those goals or about to cross a threshold. This could include, for example, if the dishwasher was turned on, and the system detected that consumption during part of the cycle of the dishwasher could push the usage outside the agreed upon limit, an alert would be shown.

In some embodiments, each behavioural instruction is associated with a reward. In the case that the performance conditions associated with the behavioural instruction have been satisfied, the reward is associated with the given one of the user accounts. For example, the reward may be determined by a resource provider that stands to benefit from the users' behaviour, and the resource provider may offer a voucher, reduction in charges, or the like.

In some cases the method includes analysing data derived from a plurality of utility meters thereby to determine whether the threshold level of resource consumption is achieved (or other goal reached) across a plurality of households. For example, the goal may be to reduce consumption in a certain area by X, and in seeking to achieve this the households in that area are provided an incentivised instruction to reduce consumption each by Y, on the prediction that sufficient households will comply to achieve the reduction in X overall.

The system may also include keeping a record of reliability for past performance and feeding into the number of requests that need to be accepted. For example, a reward X for a reduction of Y over time Z is effective by V amount in this region (or for a specific person or given a specific weather condition) where a reward of Q for a reduction R over time S is effective by T in this other region (or for this person or given a particular weather condition). A particular user or set of users may 99% of the time stick to the agreed goals where as another set of users may 60% of the time stick to the goals. This analysis would then be used to predict exactly how many requests need to be sent and accepted to achieve a certain amount reduction total in the grid.

### Smartphone Assisted Learning

It will be appreciated that various learning algorithms are used thereby to enhance predictions of actual physical appliance utilisation based on observed resource consumption. Some embodiments provide methods for enhancing learning based on interaction with a user's smartphone device, for example by asking questions thereby to validate predictions.

An exemplary method includes analysing resource meter monitoring data, wherein the data is indicative of resource consumption as a function of time for a meter associated with a user account, identifying data indicative pattern deviation in resource consumption; and determining that the pattern deviation in resource consumption is not associated with a known resource consumption element for that user account. That is, “unexpected” or “previously unknown” behaviours are identified. The pattern deviation may be indicative of increased or decreased resource consumption.

Where predefined condition(s) are met (noting that not all deviations will give rise to a decision to provide a notification) in respect of a given observed pattern deviation, the method includes causing a client device associated with the user account to display an interface for receiving input from a user, wherein the input is indicative of a specified resource consumption element (such as an appliance). For example, the user is asked a question regarding resource consumption, for example whether they have just activated/deactivated a particular element, whether they are using a given element in an unusual manner, or the like. The method then includes, depending on the user input, determining that the pattern deviation in resource consumption is attributable to the specific resource consumption element. For example, a prompt of “did you just turn on your dishwasher” is responded to with “yes”, and the deviation is then verified as being attributable to the activation of a dishwasher. Another example, a prompt of “Did you turn on a heater, or a stove, or something else” is responded to with “heater”, “stove” or “neither” better trains the system to understand the differences between similar loads.

In some cases, based on predictions, the smartphone interface displays one or more potential resource consumption elements, such that the user is enabled to select one of the potential resource consumption elements as the specific resource consumption element (or, in some cases, identify another with which not displayed).

Similar concepts are applied in reverse thereby to allow users to conduct their own experiments. For example, a user is able to determine power consumption for a particular appliance being used (for example via a “monitor and report now” command). In some cases instructions for particular experiments are communicated to user smartphone devices (for example step-by-step instructions for activating and deactivating certain appliances, and/or using them in prescribed ways, thereby to collect experimental data from meter behaviour).

### Competitive Resource Consumption Functionalities

Some embodiments provide functionality whereby resource consumption data is displayed in the context of a competitive arrangement. That is, the server maintains access to utility consumption usage for a plurality of utility meters, wherein each utility meter is associated with a user account, and provides data to a client device associated with a given one of the user accounts, wherein the data configures a software application executing at that client device to display, via a graphical interface, data representing a defined aspect (or aspects) of resource consumption associated with the user account relative to the same defined aspect of resource consumption associated with one or more further user accounts. For example, the aspect (or aspect) may relate to actual consumption, change in consumption, carbon footprint, change in carbon footprint, and so on.

The one or more further users are one or more further users having corresponding attributes to the user (for example in terms of location, household size, historical consumption, workplace, children's school, or the like). The one or more further users and the user are collectively associated with a common competitive activity (for example by the creation of leagues and the like).

The smartphone graphical interface is configured to provide data representing the status of the common competitive activity. This display is not necessarily limited to participants in the activity, and in some embodiments functionality is provided thereby to enable spectators.

To further encourage reductions in electricity consumption, the device is optionally configured to make suggestions that would strengthen a lead or give a struggling competitor an edge. For example, if the system could calculate and give notice that “you use your space heater for 10 min less a day, you′d move up a place.” Notifications could also be made if someone is catching up or falling behind.

### Enabling Changes in Resource Provider

In the example of FIG. 1A, server 100 includes (or maintains access to) tariff data from multiple resource providers. In overview, some embodiments provide computer implemented methods for displaying resource consumption data to users, the method including: maintaining access to utility consumption usage for a plurality of utility meters (wherein each utility meter is associated with a user account) and, for a given user, providing data to a client device associated with a given one of the user accounts, wherein the data configures a software application executing at that client device to display, via a graphical interface, data representing:

(i) data indicative of a cost associated with resource usage based on a current utility provider; and

(ii) data indicative of a cost associated with resource usage based on charges associated with one or more further utility providers;

The “cost” may be expressed in financial terms, environmental terms, or other terms.

The method additionally includes receiving, from the client device, a request to change to a selected one of the one or more further utility providers; and providing a signal thereby to cause the user to be changed to the selected one of the one or more further utility providers. In this manner, the collected meter data is used to enable user with information to change between utility providers based on potential for cost savings. This may be based on either or both of:
Historical data (for example applying the consumption charges for a specific one of the providers to usage data associated with the user, thereby to determine the cost associated with resource usage based on charges associated with one that provider).
Forecasted data (for example applying the consumption charges for a specific one of the providers to forecasted usage data calculated for the user, thereby to determine the cost associated with resource usage based on charges associated with one that provider).

In some embodiments resource providers may upload to the server pricing data specific to predefined usage profile types. Furthermore, in some cases, a feedback loop arrangement may be implemented such that a tariff may be tailored over time based on a user's behaviour (for example peak vs. off-peak usage). Additionally, in some cases, notifications may be provided when better pricing plans become available.

As different electricity consumption charging/billing plans can be complicated, it is important for the actual usage to contain information about how much energy was used, and when that energy was used (to account for on-peak and off-peak rates, for example). It also helps to know the billing cycle as well as how energy usage changes throughout the year. Typical ways that energy bills are paid by a user should also be identified and tracked, like paying by credit card or paying late, since these actions/practices incur additional fees that may vary dependent on the electric company and charging/billing plans.

### Monitoring Human Behaviour

In some embodiments meter monitoring is used to enable an indirect form of human monitoring for example in the context of monitoring health/activity of elderly persons living alone.

One embodiment provides a computer implemented method for enabling monitoring of a human behaviour based on resource consumption, the method including: maintaining access to utility consumption usage for a plurality of utility meters, wherein each utility meter is associated with a user account; for a first user account, monitoring utility consumption data, thereby to determine daily routine data; and in the case that a threshold deviation from the daily routine data is observed, providing a notification to a second user who is subscribed to monitor the first user.

Another embodiment of the above method gives the primary user a recommendation that is not related to reducing energy usage. For example, if it is detected that no kitchen appliance has been used today, send an alert to the user “Did you eat today?” or if it detects that laundry hasn't been done in a week it may ask “Have you done your laundry lately?” to encourage the user to undertake such activities. It may also alert a second user at the same time, or perhaps if no change is measured with in a period of time.

In one example, a threshold deviation from the daily routine includes determining that a predefined appliance has not been used during a defined time period. For example, this can show that a kettle has not been used, fridge not opened, lights left turned off, laundry not done, etc. In another example, a threshold deviation from the daily routine includes determining that a predefined appliance (or combination of appliances) has been used for greater than a threshold anticipated period. For example, there may be an alert if an oven has been left turned on, or the like.

These notifications are provided to a mobile device associated with a person registered to monitor premises associated with the meter (or meter monitoring device). Preferably user-controlled tailoring is enabled, thereby to assist users in monitoring for specific details.

In some cases monitoring functionalities allow a user to monitor their own home, for example to determine activity when they are not present. For example, this may be used to check on a cleaner or the like. In some embodiments this form of monitoring is enhanced by the user of scheduling data, thereby to compare resource consumption against anticipated scheduled events.

Other forms of monitoring are present in further embodiments, including blackout monitoring (for example identifying where multiple users reporting stopped or who reported zero consumption simultaneously and reporting that information to an electric company).

One embodiment provides a method for monitoring energy consumption of a dwelling or other room, apartment, house or building and identifying aberrant behaviour through energy usage. Identifying aberrant behaviour may include non-aberrant behaviour signals that may enhance aberrant behaviour signals when they appear. For example, an “everything is fine” signal may enhance a “something went wrong signal” because it provides reassuring information, like the system is still working. The advantage of using an electrical stream is that it is relatively inexpensive, unobtrusive and easy to install.

One embodiment provides a method for using identified aberrant behaviour using metered data in real-time and alerting concerned parties. For example, this may include someone whose heater has broken (and hence requites urgent attention, a parent that wants to make sure their child got home, or an independent living facility which wants early warning of trouble. Metered data may include electric, water, gas and/or any utility meter that enters the home/dwelling. This is in some embodiments extended for passive monitoring via monitoring for expected electricity consumption practices, and reporting on exceptions. For example, this is applied in respect of an individual is elderly, or independent but fragile in some way. For example, a hypothetical Grandma may be known via historical data to make a cup of tea every night within a known time period (for example before bed), and have a cup of coffee every morning. A message is delivered to one or more subscribed third parties thereby to confirm adherence and/or deviation from the known practices. Another example is a known behavior whereby kids get home from school they and turn on the TV; this is used to drive a notification to represent whether or not the kids have returned home as expected. A combination of automated and/or manual trigger points may be used.

One embodiment provides extends such monitoring functionalities by utilizing other connected sensors (preferably WiFi, ZigBee, Bluetooth, etc) thereby to add additional information to the data stream. For example, other connected electrical sensors may provide finer resolution detail. Another example would include non-electrical sensors, such as an “I am fine” button, or a networked pressure sensor to detect bed movement.

One embodiment provides a monitoring method where the other connected sensors include sensors built into a smartphone, tablet, smart-watch, or portable computing device. This allows monitoring of when a user leaves a house (for example via GPS), or when one is about the leave the house (if for example by detecting could detect through a Jawbone or Fitbit device that someone was putting on their jacket, or a user was putting on their running shoes through an in-shoe sensor).

One embodiment provides a method that profiles energy use patterns to specific people, and enables generation of alerts to respectively specific to those people. For example, a maid or a pool boy use energy in a different way than the owner does. These consumption patterns are profiled enabling tracking of, for example, how long the vacuum was on to verify when the cleaning service started and ended, or for how long the pool boy actually cleaned the pool.

### Safety Rating

In some embodiments meter data may be used to assist in assessing insurance claims, for example in the case of a fire to determine whether there was a surge in power, or perhaps a stove or heater left on. There are also applications in the context of intrusion detection and the like.

In some cases safety ratings are determined on an ongoing basis, for example to assist insurance companies in determining risk and setting premiums. One embodiment includes a computer implemented method determining a safety rating, the method including: maintaining access to utility consumption usage for a plurality of utility meters, wherein each utility meter is associated with a user account; for a first user account, monitoring utility consumption data, thereby to determine whether a predefined unsafe practice is observed; and updating a safety rating associated with the user based on observance of a predefined unsafe practice.

This may result in increasing a safety rating where particularly safe practices are observed (for example powering down/possibly unplugging devices during a lightning storm) or decreasing in the case of unsafe practices (for example leaving the heater on when leaving the house). Suggestions could be made to turn this off from a safety perspective.

### Other Functionalities

In some embodiments resource consumption monitoring is used thereby to provide information about secondary resource consumption. For example, this may include providing information about product lifespans (warning when light bulbs may need replacement, or when a clothes dryer is nearing the end of its intended lifespan), usage of consumables (for example monitoring of bread via a toaster, or detergent via a dishwasher). For example, one embodiment provides a method including: defining a record representative of a powered item, wherein the record includes a value representative of anticipated product lifespan. The value representative of anticipated product lifespan is for an anticipated lifespan based upon usage. The method further includes, based on monitoring of meter data, determining when the powered item is in use, and updating the record based on that use. This monitoring enables a comparison between powered usage of the device, and the anticipated lifespan. This comparison is used, for example, to enable reporting on anticipated product lifespan based on observed usage as a function of time, the provision of alerts when the lifespan is approaching completion, and so on.

In some embodiments the lifespan is for a powered item. In some embodiments the lifespan is for a consumable utilised by the powered item.

In some embodiments, the comparison is used to provide notifications (such as a reminder) to the user. In further embodiments the notifications are used thereby to enable delivery of tailored marketing material to the user. For example, a supermarket may offer a coupon on detergent for a house that may be low on detergent. The delivery of marketing material based on user profiling based on power consumption has further application. For example, in some cases marketing material is triggered responsive to identification of defined appliance utilization practices. For example, if a given user I observed to use a microwave at a threshold level of regularity, a supermarket may offer discounts on microwave dinners (whereas someone who does not use a microwave a lot or does not own a microwave (or even whose microwave just broke down) may get a notification for a deal on stove top meals or takeout.

In some embodiments resource consumption monitoring is used to enable enhanced billing. For example, billing information may be split out on shorter-than-standard periods (for example to attribute costs during short-term occupancies) or between people in share accommodation (for example by associating appliances with people).

In some embodiments, a bill estimates are provided based on processing of data obtained from meter monitoring as discussed herein. Electricity is in some cases prepaid on a budget, and money refunded if a user deviates via their actual spend rate. Such a refund may be direct, into a savings account (or to a charity, etc). Bill estimate is based on historical use. Budgets could be set per appliance (for example so that a user known know how many more times you can use a given appliance, such as a washing machine, before the end of the month). Notifications can be specific to that appliance.

In some embodiments a television is isolated and analysed to determine station what is being viewed (for example by comparing with known power consumption signatures for known television stations, or in some cases movies). This process can be used to create data for TV ratings and the like.

One embodiment provides a method for changing the behaviour of an individual for the optimization of power, energy, CO2-emissions produced or cost, based on variable time rate, fixed energy rate data. For example, a method may include setting a budget and warning users if they are endanger of missing that budget. They can also track to see how close they are to meeting their budget.

In some cases a given user's data is compared to others such as specific users through social networks, de-personalised demographic based on age/number of people in the house/neighborhood and the like, or as a competition (for example a league created based on people in a common school or workplace). This is a moving budget. Alerts are in some cases generated to warn when people are winning or losing, or where positions are changing. Users may get to send a predefined or custom alert to the competitors in order to gloat.

One embodiment provides a method for indicating the success of meeting a specific target (for example a consumption reduction target_{—} by linking performance on screen elements such as movement and color. A background of red can directly indicate that at this rate, the target will be missed while green could indicate on target and blue under target. And linking usage to on screen movement of line moving in a circle, simulating a meter disc spinning, would visually indicate how much power is being used in real-time without having to read a number directly.

One embodiment provides a method like the one above, where the movement or color change is displayed via a standalone device which is networked into the system. This is in some embodiments a glowing orb one leaves on their living room table or a fridge magnet or something in the main house that doesn't need to be turned on to be seen. Vibration or sound may also be an indicator along with any combination.

One embodiment provides a method like the one above where the above displays images, which change to different scene dependent on the success level.

One embodiment provides a method for choosing an energy supplier based on an optimization of power, energy, CO2-emissions produced or cost based on actual historical energy usage and/or predicted energy usage. One embodiment provides a method where that is based on variable time rate, fixed energy rate data.

One embodiment provides a method of detecting broken or non-optimal appliances, by processing power consumption data representing a given appliance of known type, and determining whether the consumption data matches a predefined pattern/condition associated with non-optimal performance. As context, every device has an electrical fingerprint, and this fingerprint can change in predictable ways when the appliance fails. For example, if the dryer still spins and blows air but the heater coil has blown, the fingerprint will change in a predictable way. It might also be the case that when that heater coil starts to go it draws more current. These events is in some embodiments used to alert the user that something is broken (possibly even identifying what part of the appliance is broken) when it breaks or even while it is breaking.

One embodiment provides a method for sizing solar systems by energy measurement. Given actual usage and locked in time possibly combined with weather data, sunrise/set data, topology data, a solar system can be best sized to somebody's actual needs.

One embodiment provides a method for active power grid stabilization. A power company can help stabilize the grid by asking users to turn things off (or on) via an alert and giving them a benefit, like extra savings on their bill in return. The power company can then confirm that their load has been reduced by checking their data stream and making sure that their power has gone down by the agreed upon amount. If the power goes above or nears the agreed level over the prescribed amount of time, the user can be warned of possibly losing their benefit directly to the phone in real-time.

One embodiment provides a method for controlling controllable appliances from real time electrical data. The real time data is in some embodiments used to control appliances. For example, if the temperature outside goes below a certain level, an air conditioner may be turned off to save power, however, a user may choose to leave the air conditioner on until the outside temperature reaches and even lower level if the power for the air conditioner is coming entirely from solar panels. In another example, a hot water heater is activated when the system identifies that someone is home.

One embodiment provides a method for controlling electrical devices through manual or automatic intervention, based on achieving an outcome founded on optimizing cost, power, carbon-footprint, or safety. This may include the use of power based readings, or the use of a single point power measurement, a single point current measurement, or a combination of the two. Control is optionally achieved over an API, for example in the context of smart appliances with Internet connectivity.

One embodiment provides a method of finding aggregate grid demand based on predictive modeling of a number of real time, high resolution electrical data streams. This includes processing of data based on home utilization (for example prediction/monitoring of whether people are home or not), appliance utilization and ongoing utilization (for example, is a user has turned on their dishwasher, it will consume an approximate known quantity electricity over a defined upcoming period), and/or knowledge of appliance presence (for example knowledge of the appliances in a given dwelling enables predictions of maximum usage). This is optionally used for purposes such as facilitating efficient purchase of power from the grid in bulk, with less waste. For example, historical analysis enables identification of regular behaviors, and identification of exceptions. In some such cases a server is configured to solicit direct feedback, for example, someone may exhibit deviation from regular patterns, so the platform may ask if they are on vacation, and so this can be confirmed (and, for example, used in the context of spot buying power or the like).

One embodiment provides a method for the creation of a marketplace based on aggregate of personal energy profiles and above predictions.

One embodiment provides a method for grid load balancing based on aggregate personal energy profiles and above predictions.

One embodiment provides a method of lowering market demand risk with spot purchasing of electricity.

One embodiment provides a method for allowing billing in real-time so that one can make micropayments of electricity (monthly, weekly, hourly, to the minute, by watthour), or allow an individual to move money into a different bank account so they have enough money to pay the bill at the end of the month.

One embodiment provides a method for reducing electrical costs given a system with predictive power where a suggestion can be applied to a predictive engine to yield a potential benefit. (“If you do X, you'll save Y”).

One embodiment provides a method to reduce electrical costs through competitive social pressure. For example, a ranking system is provided so that, as people reduce their consumption, they move up or down in the ranking. Ranking doesn't have to be real, but can be. Some embodiments use ranking groups, for example, a “novice” group to “expert energy saver” group).

One embodiment provides a method for reducing electrical costs by allowing users to compare directly to each other or themselves at different points in time (like a corresponding time in the previous year).

One embodiment provides a method for changing reporting characteristics based on cultural standards or user selections, which are associated with respective reporting profiles. For example, these profiles may range from a “tell me everything about my electricity consumption” profile to a “only warn me in the case of a serious problem” profile.

One embodiment provides a method to reduce electrical costs through slight misrepresentation of data. For example, this may include reporting that a given average is slightly lower than it is, thereby to encourage very efficient users from becoming complacent. There may be many points of comparison; one approach includes changing points of comparison so that the person being compared to always higher than the average.

One embodiment provides a method for creating a marketplace for energy efficient appliances.

One embodiment provides a method for estimating the amount of time the fridge door is open based on analysis of electricity consumption via meter monitoring.

One embodiment provides a method for estimating line voltage given a current transformer and power meter reading for one point of measurement, or a number of points of measurement in the same electrical area.

One embodiment provides a method for estimating high resolution power use given a current transformer, and a voltage reading for the electrical area.

One embodiment provides a method for figuring out mains heath given a distributed data stream. (The electricity companies could estimate areas for blackout, things like that. Or maybe an area voltage drop.)

One embodiment provides a method for alerting a user based on a critical function. (for example, instead of saying the power is out, one could say, the fridge stopped working, or give a list of things to do “the power went out, do not open the fridge unless necessary, buy ice, unplug appliances in case of power surge. etc”) That is, give the relevant critical information exactly when it is needed.

One embodiment provides a method for predicting a failing appliance and possibly how it fails. If given an electrical fingerprint of a device and how it functions, there are also fingerprints of how it behaves when it starts to fail. Those could also be looked for.

One embodiment provides a method for measuring house wiring going bad through consumption data over time. A method for reducing risk of fires for left on appliances.

One embodiment provides a method for improving forensic investigations by providing an off-site energy stream. For example processing is performed thereby to determine what is on, what is off, and in some cases what is malfunctioning. If devices turned off in a certain order, this may be used to identify, by way f example, a speed and direction in which a house burnt down.

One embodiment provides a method for varying alerts dependent on time of day or users usage patterns, (don't give noncritical alerts while sleeping, for example.)

In some embodiments, a software application that does not require any specific hardware installation (such as a beacon device) is provided. This is optionally used to encourage a user to gain a preliminary threshold interest in resource consumption, prior to that user committing to purchase a beacon device (or other such hardware). For example, one could take a photo of their meter occasionally, perhaps between bills, to see if the estimates the companies are providing are accurate (or to help estimate bills for a given period). This could also allow pre-customers to use the revenue generating rate switching portion of the app (or other useful portion of the app) without a need for the specific meter monitoring hardware.

In some embodiments, if someone takes a photo of a bank of meters (as is customary in an apartment building) all meter data is preferably funneled to the appropriate user accounts by reading of the serial numbers on the individual meters.

The beacon device could in such an arrangement be offered to consumers as a solution/alternative to manually photographing meters. Beacon ordering is in such cases preferably facilitated directly through the app.

In some embodiments, voltage of power lines is inferred. This is achieved via power and current measurement on the same line or on a combination of lines and applying Kirchhoff's Laws. It will be appreciated that voltage should locally be the same. So, all the appliances should be running at the same voltage even though that voltage may change over time. If a single voltage measurement can be made by an appliance or smart appliance or locally on a grid from a neighbour's house on the same local grid then the voltage for the user's house is known and can be used in part to calculate power. Another way is to analyse a known reliable load. By looking at, say, the load of fridge, the motor that turns on and off may pull different amount of current at different voltages. By combining analysis of multiple appliances across multiple files, a better voltage can be found.

One embodiment provides a method for predictive power grid stabilization. If a number of users allow the power grid company to see their data, the power grid company can use this data to create predictive load profiles based on the sum of the individual usage of the people living in that area. This may include data about which appliances are in these homes so, for example, the power company could watch at which temperatures do individuals turn on their air conditioner and knowing which air conditioner (or how much it consumes) that individuals own, could correlate the demand given certain weather patterns.

One embodiment provides a method for more calculating energy rates. If a user provides historical data to a potential power company, the power company can provide better rates because they can be less conservative with their predictions with more information.

One embodiment provides a method for profile device behaviour such as how long the refrigerator door is open or which wash cycle uses the least resources.

One embodiment provides a method for improving an algorithm by directly asking for feedback in real time. When an element from a data stream is not recognized, then a user can be asked directly for feedback. This may be in the form of a message to a smart phone, tablet device, other computing device, or even via a SMS or email (connection training).

One embodiment provides a method for improving an algorithm by the use proactively giving feedback in real time. For example, the user may have the option to open the smartphone application (or other software interface on any computing medium) and input that they just turned on the dishwasher in the last five minutes. (directed training)

One embodiment provides a method like that above, but where the system randomly prompts the user a question if certain things are on or off (random directed training).

One embodiment provides a method for confirming predictions through direct feedback. An interface that shows the current predictions, and the user can then look at some or all of the predictions about which appliances are on or off and then correct the incorrect ones. (confirmation training).

Exemplary Devices, Sensors and Mounts

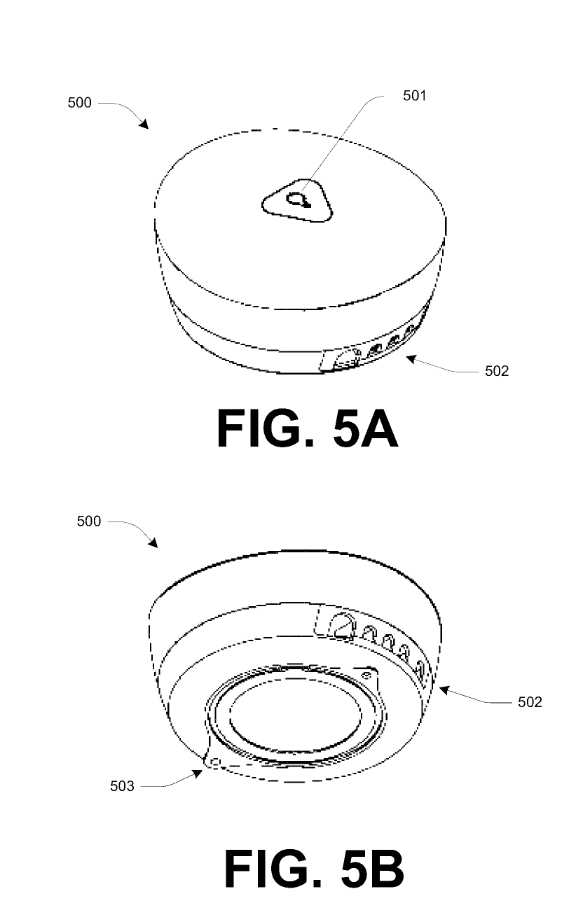

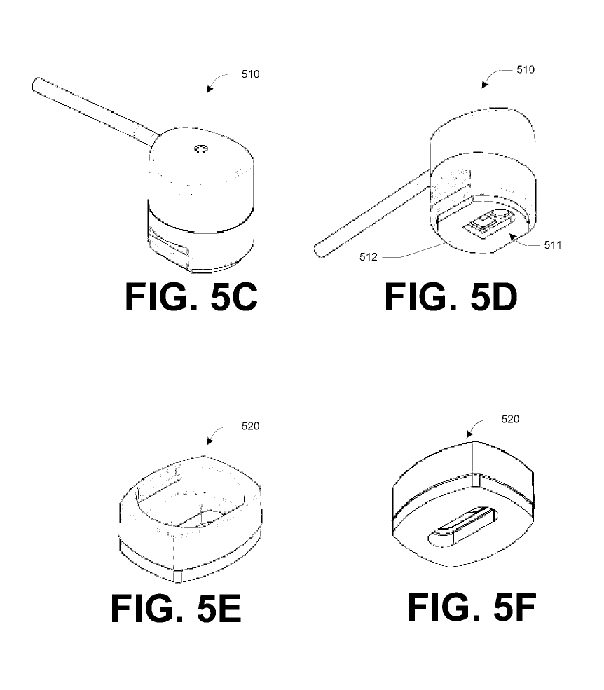

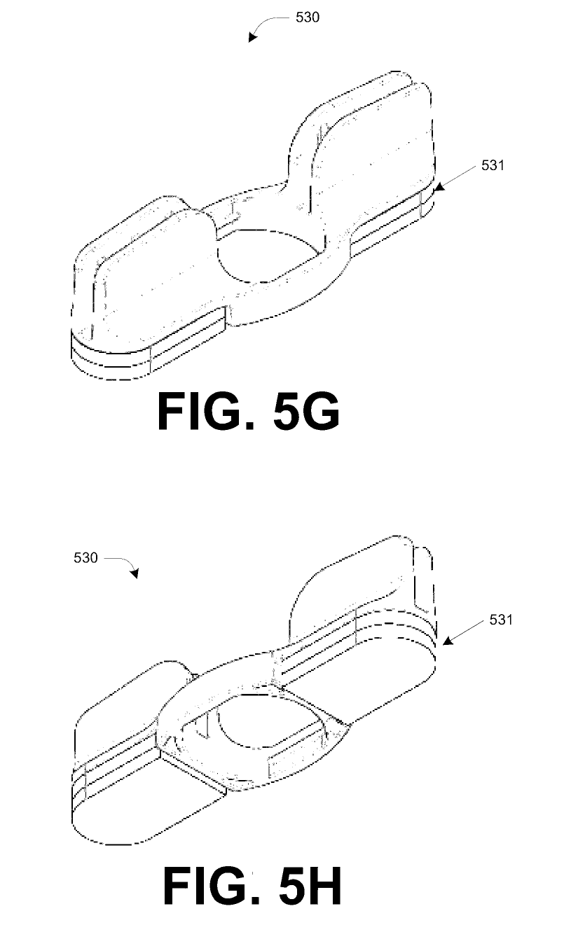

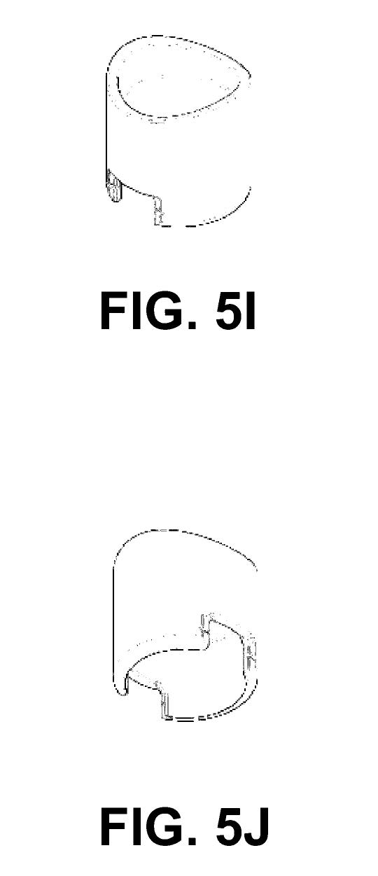

FIG. 5A and FIG. 5B illustrate a beacon device 500 according to one embodiment. In the illustrated embodiment, the beacon device hardware is contained in a housing, the housing including a button 501. The housing is configured such that opening of the housing necessitates activation of button 501 which, as described further above, may provide a security feature (for example providing an alert in the case that the housing is opened).

The housing includes a plurality of openings 502, which allow for sensor cables to pass. In this embodiment, the openings are configured such that connecting and/or disconnecting a sensor requires the housing to be opened. This again provides a security feature, in the sense that button 501 provides a signal indicative of housing opening prior to any sensor being disconnected.

A mounting formation 503 allows the beacon device to be screwed into an underlying surface, which may be an adhesive mount. Again, accessing screws requires opening of the housing. In some embodiments the base of the beacon device housing is adhesive for mountain without a need for screws.

FIG. 5C and FIG. 5D illustrate a sensor according to one embodiment. This is a dual-use sensor as described above, having an ambient light sensor plus and IR proximity sensor. These make observations via an opening 511. The sensor includes a base 512, which is formed of a resilient material. This resiliently abuts against a surface (such as the mounting bracket of FIG. 5E, or a window covering a disc meter component if the mounting bracket of FIG. 5G is used).

FIGS. 5E and 5F illustrate an exemplary mounting bracket 520 for a flashing LED type meter. This mounting bracket is configured to snap-lockingly engage with sensor 510. A user mounts bracket 520, which preferably has an adhesive base. Correct mounting is facilitated by ability to see through the bracket's lower aperture, which should overlie a LED light. The bracket includes a base against which the sensor abuts, providing a gap between the sensor and the meter surface (which is important for proximity detection).

FIGS. 5G and 5H illustrate an exemplary mounting bracket 530 for a spinning disc meter. This includes a 2-part base 531. The lower portion has an adhesive underside that is adhered to a meter. The upper side of the lower portion and the underside of the upper portion are configured to connect to each other, for example via Velcro, Dual Lock or the like. A user first mounts the lower portion, and then is able to repeatedly re-mount the upper portion (which is connected to the primary bracket body into which sensor 510 is engagable) to achieve correct alignment. A lens component shown in FIG. 5I and FIG. 5J is optionally inserted into mounting bracket 530 to assist in alignment. For example the lens includes markings or the like to indicate correct alignment with respect to a spinning disc. Once alignment is confirmed using the lens, the lens is removed, and sensor 510 is installed into the mounting bracket.

### Exemplary Client-Server Framework

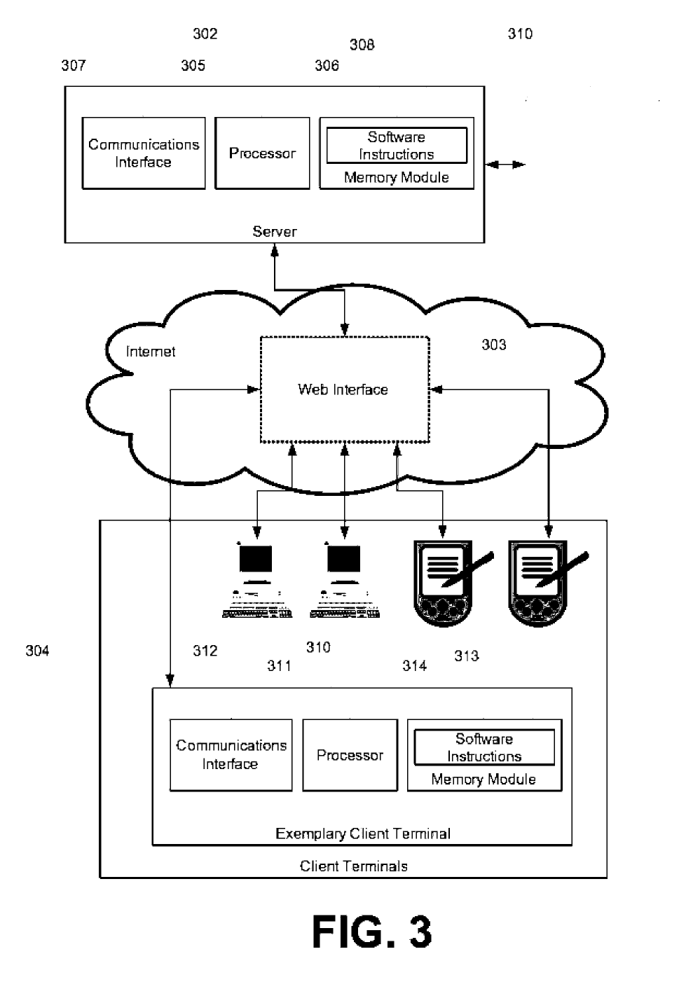

In some embodiments, methods and functionalities considered herein are implemented by way of a server, as illustrated in FIG. 3. In overview, a web server 302 provides a web interface 303. This web interface is accessed by the parties by way of client terminals 304. In overview, users access interface 303 over the Internet by way of client terminals 304, which in various embodiments include the likes of personal computers, PDAs, cellular telephones, gaming consoles, and other Internet enabled devices.

Server 303 includes a processor 305 coupled to a memory module 306 and a communications interface 307, such as an Internet connection, modem, Ethernet port, wireless network card, serial port, or the like. In other embodiments distributed resources are used. For example, in one embodiment server 302 includes a plurality of distributed servers having respective storage, processing and communications resources. Memory module 306 includes software instructions 308, which are executable on processor 305.

Server 302 is coupled to a database 310. In further embodiments the database leverages memory module 306.

In some embodiments web interface 303 includes a website. The term “website” should be read broadly to cover substantially any source of information accessible over the Internet or another communications network (such as WAN, LAN or WLAN) via a browser application running on a client terminal. In some embodiments, a website is a source of information made available by a server and accessible over the Internet by a web-browser application running on a client terminal. The web-browser application downloads code, such as HTML code, from the server. This code is executable through the web-browser on the client terminal for providing a graphical and often interactive representation of the website on the client terminal. By way of the web-browser application, a user of the client terminal is able to navigate between and throughout various web pages provided by the website, and access various functionalities that are provided.

Although some embodiments make use of a website/browser-based implementation, in other embodiments proprietary software methods are implemented as an alternative. For example, in such embodiments client terminals 304 maintain software instructions for a computer program product that essentially provides access to a portal via which framework 100 is accessed (for instance via an iPhone app or the like).

In general terms, each terminal 304 includes a processor 311 coupled to a memory module 313 and a communications interface 312, such as an internet connection, modem, Ethernet port, serial port, or the like. Memory module 313 includes software instructions 314, which are executable on processor 311. These software instructions allow terminal 304 to execute a software application, such as a proprietary application or web browser application and thereby render on-screen a user interface and allow communication with server 302. This user interface allows for the creation, viewing and administration of profiles, access to the internal communications interface, and various other functionalities.

### Interpretation

Unless specifically stated otherwise, as apparent from the following discussions, it is appreciated that throughout the specification discussions utilizing terms such as “processing,” “computing,” “calculating,” “determining”, analysing” or the like, refer to the action and/or processes of a computer or computing system, or similar electronic computing device, that manipulate and/or transform data represented as physical, such as electronic, quantities into other data similarly represented as physical quantities.

In a similar manner, the term “processor” may refer to any device or portion of a device that processes electronic data, e.g., from registers and/or memory to transform that electronic data into other electronic data that, e.g., may be stored in registers and/or memory. A “computer” or a “computing machine” or a “computing platform” may include one or more processors.

The methodologies described herein are, in one embodiment, performable by one or more processors that accept computer-readable (also called machine-readable) code containing a set of instructions that when executed by one or more of the processors carry out at least one of the methods described herein. Any processor capable of executing a set of instructions (sequential or otherwise) that specify actions to be taken are included. Thus, one example is a typical processing system that includes one or more processors. Each processor may include one or more of a CPU, a graphics processing unit, and a programmable DSP unit. The processing system further may include a memory subsystem including main RAM and/or a static RAM, and/or ROM. A bus subsystem may be included for communicating between the components. The processing system further may be a distributed processing system with processors coupled by a network. If the processing system requires a display, such a display may be included, e.g., a liquid crystal display (LCD), Electrophoretic Display (EPD), or a cathode ray tube (CRT) display. If manual data entry is required, the processing system also includes an input device such as one or more of an alphanumeric input unit such as a keyboard, a pointing control device such as a mouse, and so forth. The term memory unit as used herein, if clear from the context and unless explicitly stated otherwise, also encompasses a storage system such as a disk drive unit. The processing system in some configurations may include a sound output device, and a network interface device. The memory subsystem thus includes a computer-readable carrier medium that carries computer-readable code (e.g., software) including a set of instructions to cause performing, when executed by one or more processors, one of more of the methods described herein. Note that when the method includes several elements, e.g., several steps, no ordering of such elements is implied, unless specifically stated. The software may reside in the hard disk, or may also reside, completely or at least partially, within the RAM and/or within the processor during execution thereof by the computer system. Thus, the memory and the processor also constitute computer-readable carrier medium carrying computer-readable code.

Furthermore, a computer-readable carrier medium may form, or be included in a computer program product.

In alternative embodiments, the one or more processors operate as a standalone device or may be connected, e.g., networked to other processor(s), in a networked deployment, the one or more processors may operate in the capacity of a server or a user machine in server-user network environment, or as a peer machine in a peer-to-peer or distributed network environment. The one or more processors may form a personal computer (PC), a tablet PC, a set-top box (STB), a Personal Digital Assistant (PDA), a cellular telephone, a web appliance, a network router, switch or bridge, or any machine capable of executing a set of instructions (sequential or otherwise) that specify actions to be taken by that machine.

Note that while diagrams only show a single processor and a single memory that carries the computer-readable code, those in the art will understand that many of the components described above are included, but not explicitly shown or described in order not to obscure the inventive aspect. For example, while only a single machine is illustrated, the term “machine” shall also be taken to include any collection of machines that individually or jointly execute a set (or multiple sets) of instructions to perform any one or more of the methodologies discussed herein.

Thus, one embodiment of each of the methods described herein is in the form of a computer-readable carrier medium carrying a set of instructions, e.g., a computer program that is for execution on one or more processors, e.g., one or more processors that are part of web server arrangement. Thus, as will be appreciated by those skilled in the art, embodiments of the present invention may be embodied as a method, an apparatus such as a special purpose apparatus, an apparatus such as a data processing system, or a computer-readable carrier medium, e.g., a computer program product. The computer-readable carrier medium carries computer readable code including a set of instructions that when executed on one or more processors cause the processor or processors to implement a method. Accordingly, aspects of the present invention may take the form of a method, an entirely hardware embodiment, an entirely software embodiment or an embodiment combining software and hardware aspects. Furthermore, the present invention may take the form of carrier medium (e.g., a computer program product on a computer-readable storage medium) carrying computer-readable program code embodied in the medium.

The software may further be transmitted or received over a network via a network interface device. While the carrier medium is shown in an exemplary embodiment to be a single medium, the term “carrier medium” should be taken to include a single medium or multiple media (e.g., a centralized or distributed database, and/or associated caches and servers) that store the one or more sets of instructions. The term “carrier medium” shall also be taken to include any medium that is capable of storing, encoding or carrying a set of instructions for execution by one or more of the processors and that cause the one or more processors to perform any one or more of the methodologies of the present invention. A carrier medium may take many forms, including but not limited to, non-volatile media, volatile media, and transmission media. Non-volatile media includes, for example, optical, magnetic disks, and magneto-optical disks. Volatile media includes dynamic memory, such as main memory. Transmission media includes coaxial cables, copper wire and fiber optics, including the wires that comprise a bus subsystem. Transmission media also may also take the form of acoustic or light waves, such as those generated during radio wave and infrared data communications. For example, the term “carrier medium” shall accordingly be taken to included, but not be limited to, solid-state memories, a computer product embodied in optical and magnetic media; a medium bearing a propagated signal detectable by at least one processor of one or more processors and representing a set of instructions that, when executed, implement a method; and a transmission medium in a network bearing a propagated signal detectable by at least one processor of the one or more processors and representing the set of instructions.

It will be understood that the steps of methods discussed are performed in one embodiment by an appropriate processor (or processors) of a processing (i.e., computer) system executing instructions (computer-readable code) stored in storage. It will also be understood that the invention is not limited to any particular implementation or programming technique and that the invention may be implemented using any appropriate techniques for implementing the functionality described herein. The invention is not limited to any particular programming language or operating system.

It should be appreciated that in the above description of exemplary embodiments of the invention, various features of the invention are sometimes grouped together in a single embodiment, FIG., or description thereof for the purpose of streamlining the disclosure and aiding in the understanding of one or more of the various inventive aspects. This method of disclosure, however, is not to be interpreted as reflecting an intention that the claimed invention requires more features than are expressly recited in each claim. Rather, as the following claims reflect, inventive aspects lie in less than all features of a single foregoing disclosed embodiment. Thus, the claims following the Detailed Description are hereby expressly incorporated into this Detailed Description, with each claim standing on its own as a separate embodiment of this invention.

Furthermore, while some embodiments described herein include some but not other features included in other embodiments, combinations of features of different embodiments are meant to be within the scope of the invention, and form different embodiments, as would be understood by those skilled in the art. For example, in the following claims, any of the claimed embodiments can be used in any combination.

Furthermore, some of the embodiments are described herein as a method or combination of elements of a method that can be implemented by a processor of a computer system or by other means of carrying out the function. Thus, a processor with the necessary instructions for carrying out such a method or element of a method forms a means for carrying out the method or element of a method. Furthermore, an element described herein of an apparatus embodiment is an example of a means for carrying out the function performed by the element for the purpose of carrying out the invention.

In the description provided herein, numerous specific details are set forth. However, it is understood that embodiments of the invention may be practiced without these specific details. In other instances, well-known methods, structures and techniques have not been shown in detail in order not to obscure an understanding of this description.

Similarly, it is to be noticed that the term coupled, when used in the claims, should not be interpreted as being limited to direct connections only. The terms “coupled” and “connected,” along with their derivatives, may be used. It should be understood that these terms are not intended as synonyms for each other. Thus, the scope of the expression a device A coupled to a device B should not be limited to devices or systems wherein an output of device A is directly connected to an input of device B. It means that there exists a path between an output of A and an input of B which may be a path including other devices or means. “Coupled” may mean that two or more elements are either in direct physical or electrical contact, or that two or more elements are not in direct contact with each other but yet still co-operate or interact with each other.

Thus, while there has been described what are believed to be the preferred embodiments of the invention, those skilled in the art will recognize that other and further modifications may be made thereto without departing from the spirit of the invention, and it is intended to claim all such changes and modifications as falling within the scope of the invention. For example, any formulas given above are merely representative of procedures that may be used. Functionality may be added or deleted from the block diagrams and operations may be interchanged among functional blocks. Steps may be added or deleted to methods described within the scope of the present invention.

1. A device that is configured to monitor a physical resource consumption meter, the device including:
an input, wherein the input is configured to receive data from a sensor device, wherein the sensor device is configured to monitor physical behaviour of a meter component of the physical resource consumption meter, wherein the meter component includes at least one of the following:
a meter component that varies velocity proportionally to resource consumption;
a meter component that varies display of visible light proportionally to resource consumption; and
a meter component that varies current proportionally to resource consumption;
a communications module configured to enable communications with a remote server device; and
a microprocessor that is coupled to the input and the communications module, wherein the microprocessor is configured to execute software instructions, wherein the software instructions configure:
operation of the sensor device;
processing of data received from the sensor device thereby to define data for transmission to the remote server device; and
operation of the communications module; and
a battery power supply, which is configured to power at least the sensor;
the communications module; and the microprocessor.

2. A device according to claim 1 wherein configuring operation of the sensor device includes:
cyclically transitioning the sensor between an active state and an inactive state based on an activation cycle, wherein the activation cycle defines:
(i) a time period for which the sensor is in an active state; and
(ii) a time period for which the sensor is in an inactive state;
selectively modifying the activation cycle based on a power management protocol.

3. A device according to claim 2 wherein: in the inactive state the sensor monitors meter component activity an provides an interrupt signal upon identification of a threshold condition; and in the active state the sensor communicates one or more values read from the monitoring of the meter component.

4. A device according to claim 1 wherein configuring operation of the communications module includes:
configuring the device to enter an active communications state based on a set of transmission rules, wherein the device is configured to transmit data to the remote server when in the active communications state; and
maintaining the communications module in an inactive or low-power state when not in the active communications state.

5. A device according to claim 1 wherein configuring operation of the communications module includes:
executing a protocol which accumulates transmission credits based on a battery conservation budget;
monitoring for the occurrence of a transmission trigger event based on a set of transmission rules; and
in the case that a transmission trigger event is observed, providing a transmission in response to the transmission trigger event in the case that there is sufficient transmission credit for the transmission.

6. A device according to claim 1 wherein the software instructions additionally configure the device to perform the following
based on input from a sensor device, recording periodic data points in a buffer;
transmitting the data points to a remote server based on a set of transmission rules, wherein the buffer is cleared following the transmission;
applying a buffer management protocol, thereby to compress the data points in the buffer in response to a set of buffer management rules.

7. A device according to claim 6 wherein compressing the data points is performed based on a compression algorithm that accurately maintains data representative of overall resource consumption.

8. A device according to claim 1 wherein the input is configured to enable selective connection to any one of a plurality of compatible sensor devices, wherein one or more of the sensor devices are configured for monitoring physical behaviour of a meter component.

9. A device according to claim 8 wherein plurality of compatible sensor devices includes a dual use sensor configured to monitor each of a spinning disc meter component and a flashing LED type meter component.

10. A device according to claim 8 wherein plurality of compatible sensor devices includes a sensor configured to monitor a contact switch type meter component.

11. A device according to claim 8 wherein plurality of compatible sensor devices includes a current transformer adapted to be coupled to a wire.

12. A device according to claim 1, wherein the device is configured to automatically detect a sensor type of a sensor coupled to the input, and execute a predefined configuration script associated with that sensor type.

13. A method for monitoring physical behaviour of a meter component thereby to determine data representative of resource consumption, the method including:
(i) operating a sensor to take multiple observation readings for a discrete period;
(ii) performing mathematical calculations thereby to determine thresholds representative of meter component events;
(iii) based on the mathematical calculations, setting at least one threshold value that is representative of observance of a meter component event; and
(iv) configuring the sensor is to provide an interrupt each time the threshold value is crossed;
such that resource consumption data is derived from processing of interrupts after the discrete period.

14. A method according to claim 13 wherein the method includes configuring the sensor to provide one or more readings in response to the threshold value being crossed, thereby to determine whether (i) to (iv) should be repeated for re-calibration.

15. A method according to claim 13 wherein (i) to (iv) are repeated periodically

16. A method for operating a device that is configured to monitor a physical meter, wherein the device includes a sensor configured to monitor physical behaviour of a meter component, the method including:
cyclically transitioning the sensor between an active state and an inactive state based on an activation cycle, wherein the activation cycle defines:
(i) a time period for which the sensor is in an active state; and
(ii) a time period for which the sensor is in an inactive state;
selectively modifying the activation cycle based on a power management protocol.

17. A method according to claim 16 wherein the inactive state corresponds to a low power mode.

18. A method according to claim 16 wherein the inactive state corresponds to state wherein no power is supplied to the sensor.

19. A method according to claim 16 wherein the power management protocol is configured to modify the activation cycle responsive to variations in an observed meter activity pattern.

20. A method according to claim 16 wherein the power management protocol is configured to modify the activation cycle responsive to a time of day.

21-92. (canceled)
